(19) United States
(12) Patent Application Publication
(10) Pub. No.: US 2016/0118343 A1
(43) Pub. Date: Apr. 28, 2016

(54) SEMICONDUCTOR DEVICE

(71) Applicant: Renesas Electronics Corporation, Tokyo (JP)

(72) Inventor: Yoshikazu TSUNEMINE, Ibaraki (JP)

(21) Appl. No.: 14/872,275

(22) Filed: Oct. 1, 2015

(30) Foreign Application Priority Data
Oct. 27, 2014 (JP) 2014-218267

(51) Int. Cl. H01L 23/528; H01L 23/522

(52) U.S. Cl. CPC H01L 23/5283; H01L 23/5223

(57) ABSTRACT

Low-voltage side wirings LWA and LWB extend in X-direction, respectively, while meandering along a main surface of a semiconductor substrate SUB. A high-voltage side wiring HAW is opposed to the meandering low-voltage side wiring LWA, and a high-voltage side wiring HWB is opposed to the meandering low-voltage side wirings LWB. The high-voltage side wirings HWA and HWB include: X-direction extending parts XA and XB extending in X-direction; and a plurality of Y-direction extending parts YA and YB extending, respectively, in Y-direction. Toward a section of the low-voltage side wiring LWA being away from the X-direction extending part XA, the Y-direction extending part YA has entered. Also, toward a section of the low-voltage side wiring LWB being away from the X-direction extending part XB, the Y-direction extending part YB has entered.

### CROSS-REFERENCE TO RELATED APPLICATIONS

The disclosure of Japanese Patent Application No. 2014-218267 filed on Oct. 27, 2014 including the specification, drawings, and abstract is incorporated herein by reference in its entirety.

### BACKGROUND

The present invention relates to a semiconductor device and, for example, can be applied suitably to a semiconductor device having an MIM (Metal Insulator Metal) capacitative element.

As one of the circuits for forming a semiconductor device, there is, for example, an A-D (analog-to-digital) converter. There is a comparator circuit in the A-D converter and, in order to compare an external signal (voltage) with a reference signal (voltage), two capacitative elements are used in many cases. The reference signal is inputted to one capacitative element and the external signal is inputted to the other capacitative element. As such capacitative elements, for example, MIM capacitative elements are used.

By comparing a potential corresponding to charges accumulated in one capacitative element with a potential corresponding to charges accumulated in the other capacitative element, relative sizes of signals are checked. In order to check the relative sizes of the signals with accuracy, it is required that there is little variation between the capacitance values of two capacitative elements. In other words, it is required that a capacitance difference between the two capacitative elements be small.

The capacitance difference between the two capacitative elements depends on the variation in processing accuracy of the two capacitative elements at the time of manufacturing a semiconductor device. For this reason, as a commonly used method for reducing the capacitance difference between the two capacitative elements, there is employed a method in which capacitances (sizes) of the two capacitative elements are set to be large with respect to variation in processing accuracy. As an example of the literature that disclosed the semiconductor device having such two capacitative elements, for example, there is Patent Document 1.

[Patent Document 1] Japanese Patent Laid-open No. 2006-228803

### SUMMARY

However, the ordinarily employed semiconductor device had the problem as follows. The two capacitative elements are to be formed in the predetermined regions, respectively, of the semiconductor substrate. This time, the present inventors have confirmed the following fact. That is, even if the capacitances (sizes) of the two capacitative elements are set to be large, depending on a positional relationship, over the semiconductor substrate, of the region where one capacitative element is formed and the region where the other capacitative element is formed, the difference between the capacitance of one capacitative element and the capacitance of the other capacitative element is not reduced.

The aforementioned and other purposes and novel features of the present invention will be made clear from the description of the present specification and the attached drawings.

A semiconductor device according to one embodiment includes a first capacitative element and a second capacitative element as a pair of capacitative elements. The first capacitative element includes a first wiring, a second wiring, and a first dielectric. The first wiring extends in a first direction while meandering along the main surface. The second wiring is opposed to the first wiring being spaced from the first wiring in a main surface direction. The first dielectric is interposed between the first wiring and the second wiring. The second capacitative element includes a third wiring, a fourth wiring, and a second dielectric. On the side opposite to the second wiring with respect to the first wiring, the third wiring extends in the first direction, being spaced from the first wiring in the main surface direction while meandering along the first wiring. The fourth wiring is opposed to the third wiring being spaced from the third wiring in the main surface direction. The second dielectric is interposed between the third wiring and the fourth wiring.

A semiconductor device according to another embodiment includes a first capacitative element and a second capacitative element as a pair of capacitative elements. The first capacitative element includes a first wiring, a second wiring, and a first dielectric. The first wiring extends in the first direction along the main surface in a meandering manner. The second wiring is opposed to the first wiring being spaced from the first wiring in the main surface direction. The first dielectric is interposed between the first wiring and the second wiring. The second capacitative element includes a first wiring, a third wiring, and a second dielectric. On the side opposite to the second wiring with respect to the first wiring, the third wiring is opposed to the first wiring being spaced from the first wiring in the main surface direction. The second dielectric is interposed between the first wiring and the third wiring.

A semiconductor device according to still another embodiment includes a first capacitative element and a second capacitative element as a pair of capacitative elements. The first capacitative element includes a first wiring, a second wiring, and a first dielectric. The second wiring is opposed to the first wiring being spaced from the first wiring in the main surface direction. The first dielectric is interposed between the first wiring and the second wiring. The second capacitative element includes a first wiring, a third wiring, and a second dielectric. On the side opposite to the second wiring with respect to the first wiring, the third wiring is opposed to the first wiring being spaced from the first wiring in the main surface direction. The second dielectric is interposed between the first wiring and the third wiring. The first wiring contains a first extending part and a second extending part. The first extending part extends in the first direction along the main surface. The second extending parts extend in a second direction intersecting the first direction, respectively, from the first extending part. At the same time, the second extending parts are arranged in the first direction at regular intervals. The second wiring and the third wiring extend in the second direction, respectively. As to the second and third wirings being arranged alternately in the first direction, among second extending parts, the second wiring is disposed in a region between one of the second extending parts and the other adjacent second extending part and, among the second extending parts, the third wiring is disposed in a region between the other second extending part and still the other adjacent second extending part. A plurality of second wirings and third wirings are positioned alternately in the first direction. The second wirings are electrically coupled to one another. Also, the third wirings are electrically coupled to one another.

According to the semiconductor device of one embodiment, a difference between the capacitance of the first capacitative element and the capacitance of the second capacitative element as the pair of capacitative elements can be reduced.

According to the semiconductor device of another embodiment, the difference between the capacitance of the first capacitative element and the capacitance of the second capacitative element as the pair of capacitative elements can be reduced.

According to the semiconductor device of still another embodiment, the difference of the capacitance of the first capacitative element and the capacitance of the second capacitative element as the pair of capacitative elements can be reduced.

### BRIEF DESCRIPTION OF THE DRAWINGS

FIG. 1 is a plan view of a semiconductor device according to First Embodiment;

FIG. 2 is a perspective cross-sectional view, in First Embodiment, taken along line II-II of FIG. 1;

FIG. 3 is a cross-sectional view, in First Embodiment, taken along line II-II of FIG. 1;

FIG. 4 shows, in First Embodiment, an equivalent circuit of paired MIM capacitative elements;

FIG. 5 is a cross-sectional view showing, in First Embodiment, one step of the manufacturing method of the semiconductor device;

FIG. 6 is a cross-sectional view showing, in First Embodiment, a step performed after the step shown in FIG. 5;

FIG. 7 is a cross-sectional view showing, in First Embodiment, a step performed after the step shown in FIG. 6;

FIG. 8 is a cross-sectional view showing, in First Embodiment, a step performed after the step shown in FIG. 7;

FIG. 9 is a cross-sectional view showing, in First Embodiment, a step performed after the step shown in FIG. 8;

FIG. 10 is a cross-sectional view showing, in First Embodiment, a step performed after the step shown in FIG. 9;

FIG. 11 is a cross-sectional view showing, in First Embodiment, a step performed after the step shown in FIG. 10;

FIG. 12 is a first plan view of a semiconductor device according to a comparative example;

FIG. 13 shows an equivalent circuit of paired MIM capacitative elements in the semiconductor device according to the comparative example;

FIG. 14 is a second plan view of the semiconductor device according to the comparative example;

FIG. 15 is a perspective cross-sectional view taken along line XV-XV of FIG. 14;

FIG. 16 is a plan view showing an example of arrangement of the paired MIM capacitative elements;

FIG. 17 is a plan view of a semiconductor device according to Second Embodiment;

FIG. 18 is a cross-sectional view, in Second Embodiment, taken along line XVIII-XVIII of FIG. 17;

FIG. 19 is a cross-sectional view showing, in Second Embodiment, one step of the manufacturing method of the semiconductor device;

FIG. 20 is a cross-sectional view showing, in Second Embodiment, a step performed after the step shown in FIG. 19;

FIG. 21 is a cross-sectional view showing, in Second Embodiment, a step performed after the step shown in FIG. 20:

FIG. 22 is a cross-sectional view showing, in Second Embodiment, a step performed after the step shown in FIG. 21;

FIG. 23 is a cross-sectional view showing, in Second Embodiment, a step performed after the step shown in FIG. 22;

FIG. 24 is a cross-sectional view showing, in Second Embodiment, a step performed after the step shown in FIG. 23;

FIG. 25 is a plan view of a semiconductor device according to Third Embodiment;

FIG. 26 is a perspective cross-sectional view, in Third Embodiment, taken along line XXVI-XXVI of FIG. 25;

FIG. 27 is a plan view, in Third Embodiment, of a semiconductor device according to a modification;

FIG. 28 schematically shows a coupling relationship of capacitative elements in a semiconductor device according to Fourth Embodiment;

FIG. 29 is a perspective cross-sectional view, in Fourth Embodiment, taken along line XXIX-XXIX of FIG. 28;

FIG. 30 schematically shows a coupling relationship of capacitative elements in a semiconductor device according to Fifth Embodiment;

FIG. 31 is a perspective cross-sectional view, in Fifth Embodiment, taken along line XXXI-XXXI of FIG. 30;

FIG. 32 shows, in Fifth Embodiment, an equivalent circuit of paired MIM capacitative elements in the semiconductor device; and

FIG. 33 is a plan view of a semiconductor device according to Sixth Embodiment.

### DETAILED DESCRIPTION

### First Embodiment

A first example of a semiconductor device having a pair of MIM capacitative elements will be explained.

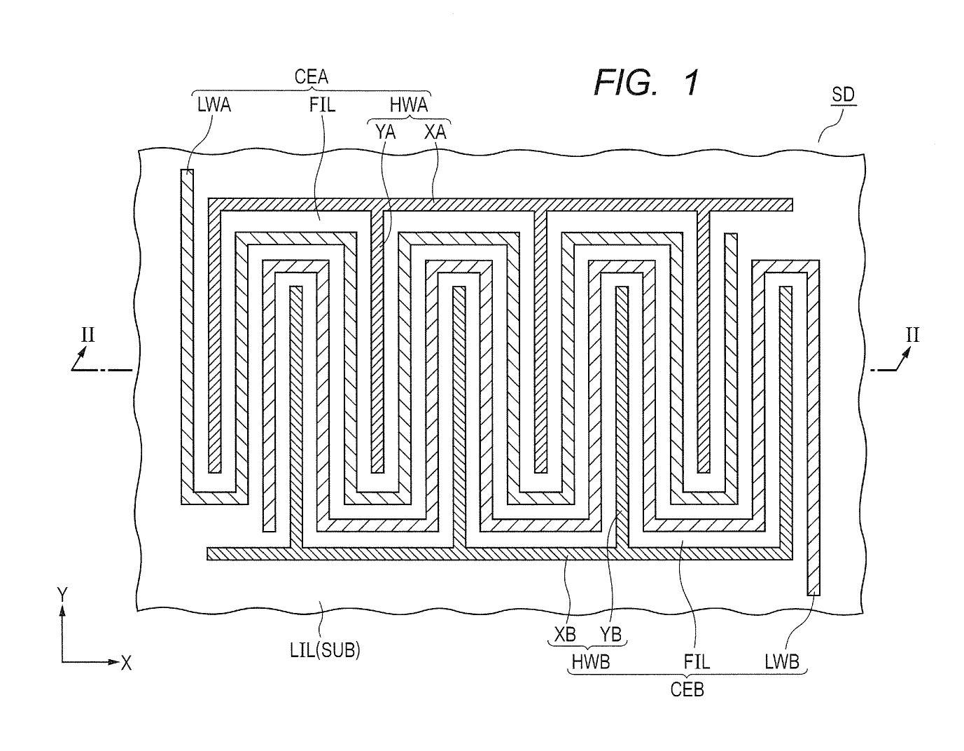

As shown in FIGS. 1, 2, and 3, in the semiconductor device SD, a lower interlayer insulation film LIL is so formed as to cover a main surface of a semiconductor substrate SUB. Over the lower interlayer insulation film LIL, a low-voltage side wiring LWA, a high-voltage side wiring HAW, a low-voltage side wiring LWB, and a high-voltage side wiring HWA are formed. So as to cover the low-voltage side wiring LWA, the high-voltage side wiring HAW, the low-voltage side wiring LWB, and the high-voltage side wiring HWA, for example, a first interlayer insulation film FIL containing silicon oxide film etc. is formed.

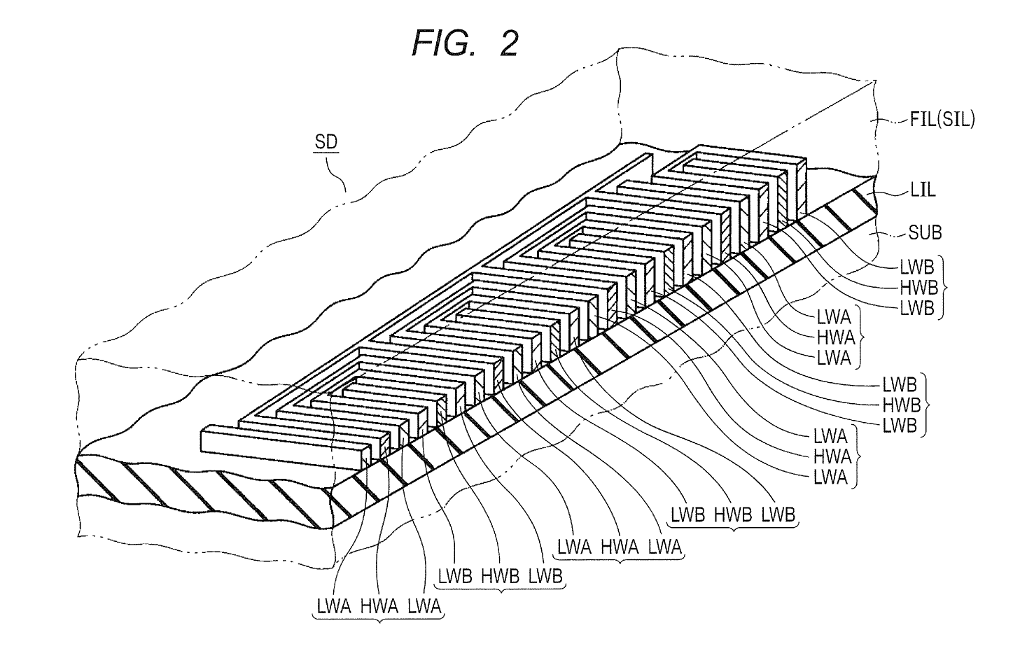

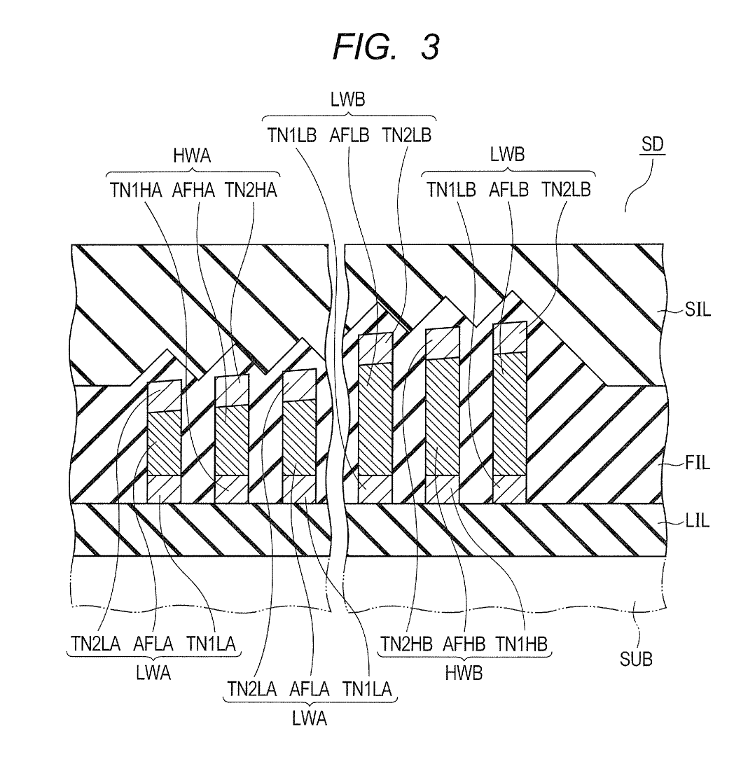

Further, a second interlayer insulation film SIL containing a silicon oxide film etc., for example, is so formed as to cover the first interlayer insulation film FIL. In addition, FIGS. 2 and 3 show, in an exaggerated manner, the unevenness (variations), in a plane of the semiconductor substrate SUB, of the thicknesses (film thicknesses) of the low-voltage side wiring LWA, the high-voltage side wiring HAW, the low-voltage side wiring LWB, and the high-voltage side wiring HWA.

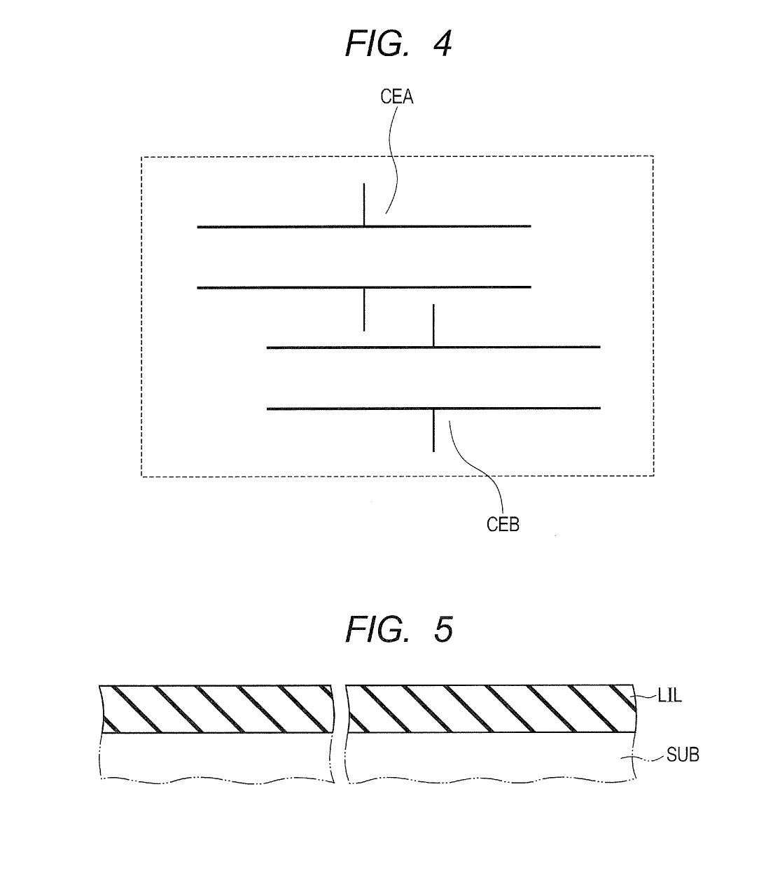

As shown in FIG. 4, the paired MIM capacitative elements include a first capacitative element CEA and a second capacitative element CEB. The first capacitative element CEA contains a low-voltage side wiring LWA (a first wiring), a high-voltage side wiring HAW (a second wiring), and part (dielectric) of the first interlayer insulation film FIL. The second capacitative element CEB contains a low-voltage side wiring LWB (third wiring), a high-voltage side wiring HWA (fourth wiring), and part (dielectric) of the first interlayer insulation film FIL.

Next, a description will be given to patterns of the low-voltage side wiring LWA, the high-voltage side wiring HAW, the low-voltage side wiring LWB, and the high-voltage side wiring HWA.

As shown in FIGS. 1 and 2, the low-voltage side wiring LWA extends in X-direction while meandering along the main surface of the semiconductor substrate SUB. The high-voltage side wiring HAW is opposed to the low-voltage side wiring LWA being spaced from the low-voltage side wiring in the main surface direction. On the opposite side of the high-voltage side wiring HWA with respect to the lower-voltage side wiring LWA, the low-voltage side wiring LWB extends in X-direction, being spaced from the low-voltage side wiring LWA in the main surface direction while meandering along the low-voltage side wiring LWA. The high-voltage side wiring HWB is opposed to the low-voltage side wiring LWB being spaced from the low-voltage side wiring LWB in the main surface direction.

Each of the high-voltage side wiring HWA and the high-voltage side wiring HWB has a comb-like shape. The high-voltage side wiring HWA includes: an X-direction extending part XA extending in X-direction; and a plurality of Y-direction extending parts YA each extending from the X-direction extending part XA in Y-direction being substantially perpendicular to X-direction. The high-voltage side wiring HWB includes: an X-direction extending part XB extending in X-direction; and a plurality of Y-direction extending parts YB each extending from the X-direction extending part XB in Y-direction.

The high-voltage side wiring HWA and the high-voltage side wiring HWB are so arranged as to sandwich the meandering low-voltage side wiring LWA and LWB. Furthermore, as to the high-voltage side wirings HWA and HWB, the Y-direction extending part YA enters toward a section of the meandering low-voltage side wiring LWA being away from the X-direction extending part XA. Also, the Y-direction extending part YB enters toward a section of the meandering low-voltage side wiring LWB being away from the X-direction extending part XB. Further, the Y-direction extending part YA and the Y-direction extending part YB are so arranged as to engage with each other. The low-voltage side wirings LWA, LWB, and the high-voltage side wirings HWA, HWB are formed according to a minimum line width and a minimum pitch of the design rule.

As shown in FIG. 2, in one cross-section along X-direction, a first-capacitative element CEA wiring group including the low-voltage side wiring LWA, the high-voltage side wiring HWA and the low-voltage side wiring LWA and a second-capacitative element CEB wiring group including the low-voltage side wiring LWB, the high-voltage side wiring HWB and the low-voltage side wiring LWB are positioned alternately along X-direction. Further, in this kind of MIM capacitative element, even an end portion of each wiring contributes to a capacitance. Therefore, it is also called a “fringe MIM capacitative element.”

Next, an explanation will be given to configurations of the thickness directions of the low-voltage side wirings LWA, LWB, and the high-voltage side wirings HWA, HWB. As shown in FIG. 3, the low-voltage side wirings LWA, LWB and the high-voltage side wirings HWA, HWB are of the three-layer configuration where an aluminum layer is laid between two titanium nitride layers.

In the low-voltage side wiring LWA, a first titanium nitride layer TN1LA, an aluminum layer AFLA, and a second titanium nitride layer TN2LA are laminated. In the high-voltage side wiring HWA, a first titanium nitride layer TN1HA, an aluminum layer AFHA, and a second titanium nitride layer TN2HA are laminated. In the low-voltage side wiring LWB, a first titanium nitride layer TN1LB, an aluminum layer AFLB, and a second titanium nitride layer TN2LB are laminated. Further, in the high-voltage side wiring HWB, a first titanium nitride layer TN1HB, an aluminum layer AFHB, and a second titanium nitride layer TN2HB are laminated.

Next, one example of the above manufacturing method of the semiconductor device will be explained. First, over a main surface of a semiconductor substrate, a predetermined semiconductor element (not shown) such as a transistor is formed. Then, as shown in FIG. 5, so as to cover the main surface of the semiconductor substrate SUB, as a contact interlayer insulating film, for example, a lower interlayer insulating layer LIL such as a silicon oxide film is formed.

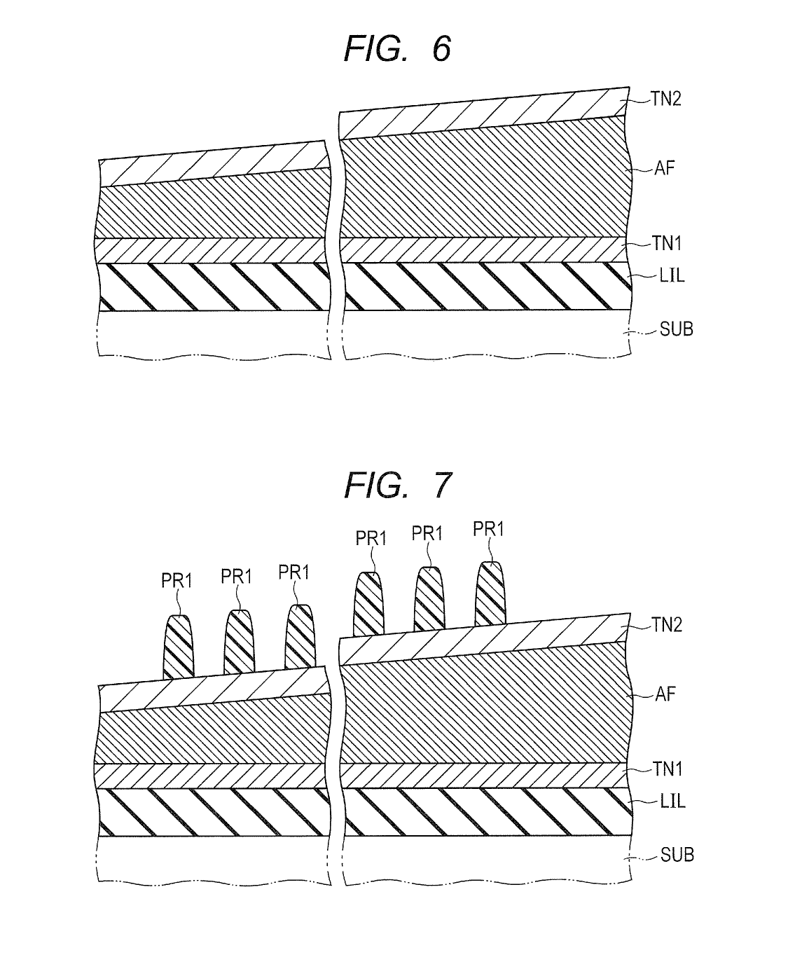

Next, as shown in FIG. 6, using a sputtering method etc., a first titanium nitride layer TN1, an aluminum layer AF, and a second titanium nitride layer TN2 are formed. In addition, as described above, FIG. 6 shows unevenness of the film thicknesses of the aluminum layer AF etc. in the plane of the semiconductor substrate SUB in an exaggerated manner, which is not intended to restrict the variation of film thicknesses of the aluminum layer AF etc.

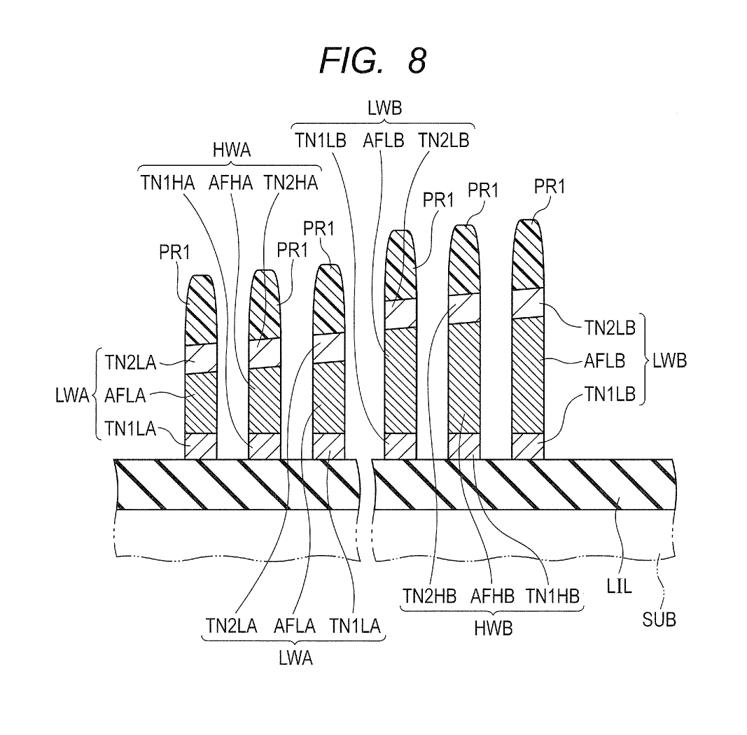

Next, as shown in FIG. 7, by performing a predetermined photomechanical process, a photo-resist pattern PR1 for forming the wiring layer is formed. At this time, the pattern PR1 of the photo-resist is formed based on the minimum line width and the minimum pitch of the design rule. Next, as shown in FIG. 8, using the photo-resist pattern PR1 as an etching mask, by applying plasma etching to the second titanium nitride layer TN2, the aluminum layer AF, and the first titanium nitride layer TN1, the low-voltage side wirings LWA, LWB and the high-voltage side wirings HWA, HWB are formed.

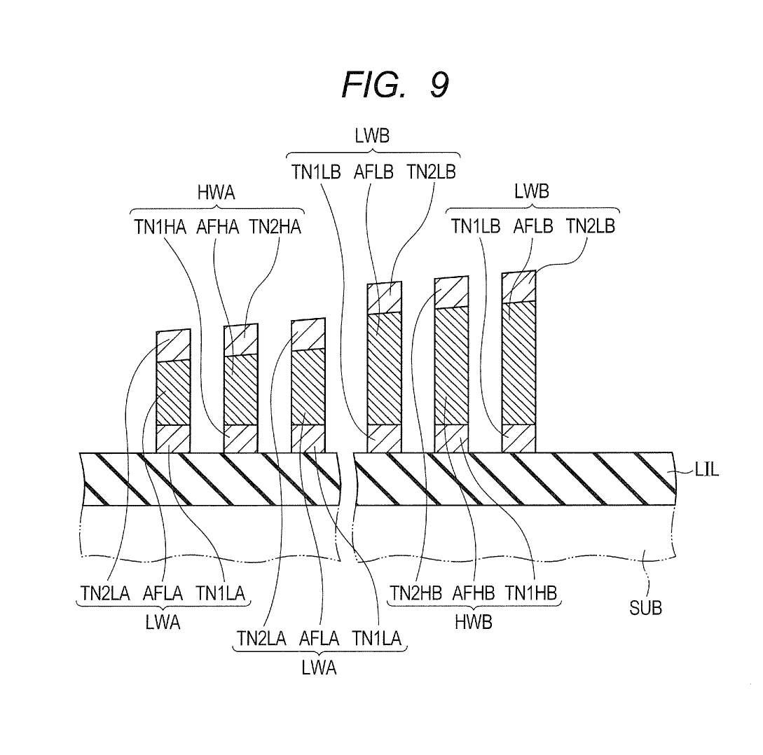

Next, by removing the photo-resist pattern PR1 by oxygen asking, as shown in FIG. 9, the low-voltage side wirings LWA, LWB, and the high-voltage side wirings HWA, HWB are exposed. In addition, if necessary, a wet process may be used together at this time.

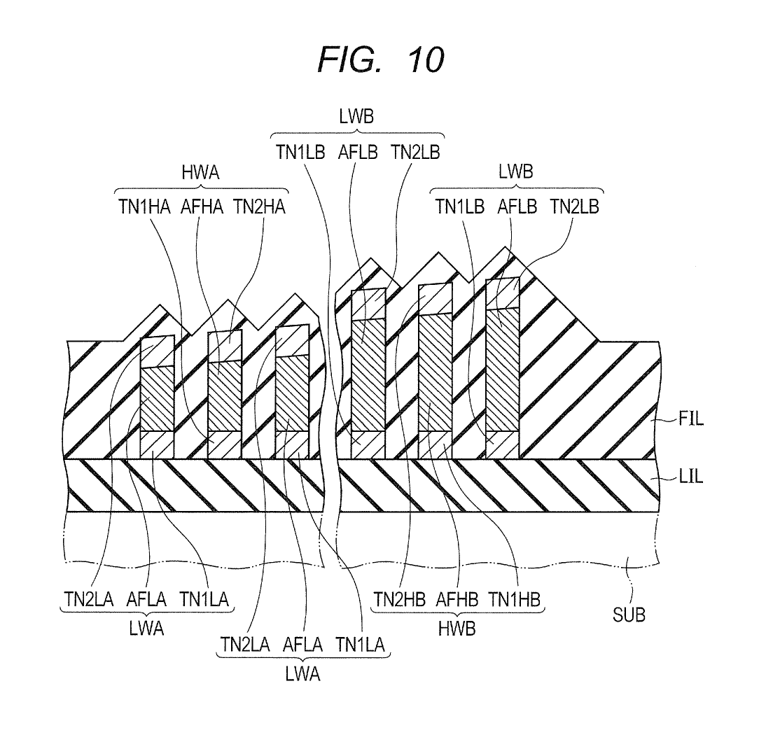

Now, as shown in FIG. 10, so as to fill each space among the low-voltage side wiring LWA, the low-voltage side wiring LWB, the high-voltage side wiring HWA, and the high-voltage side wiring HWB, for example, by a high-density plasma CVD (Chemical Vapor Deposition) method, a first interlayer insulation film FIL containing a silicon oxide film is formed. For the film thickness of the first interlayer insulation film FIL, such a film thickness is preferable as not to expose the second titanium nitride layers TN2LA, TN2LB, TN2HA, and TN2HB.

The method of forming the first interlayer insulating film FIL is not limited to the high-density plasma CVD method. So long as the performance of a semiconductor element is conformable to a process, the first interlayer insulating film FIL may be formed using a thermal CVD method, a sol-gel method, etc.

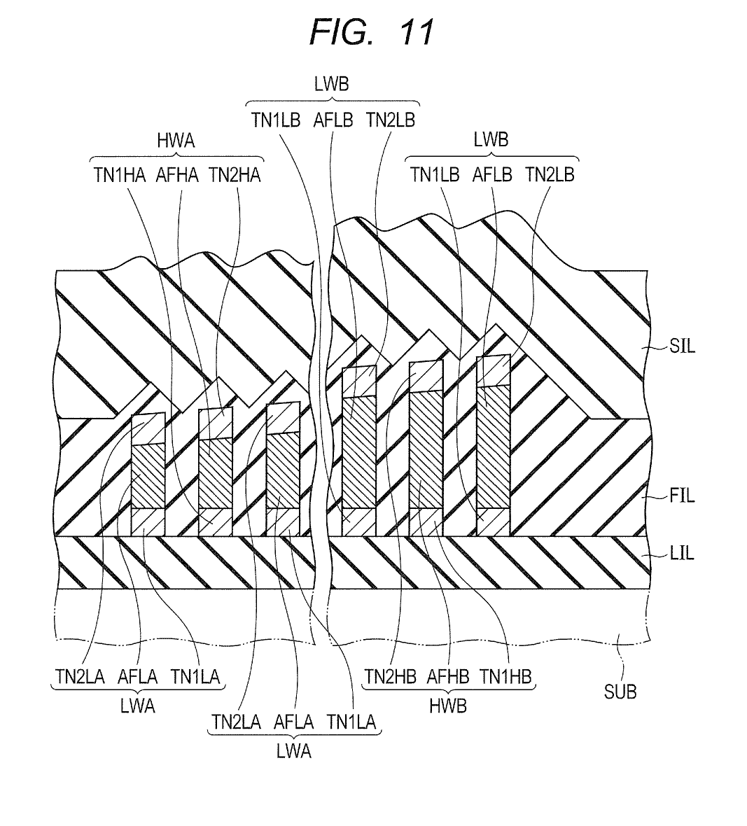

Next, as shown in FIG. 11, for example, by an ordinarily employed plasma CVD method, so as to cover the first interlayer insulating film FIL, a second interlayer insulation film SIL containing a silicon oxide film is formed. As to the method of forming the second interlayer insulating film SIL also, so long as the performance of the semiconductor device is conformable to a process, the second interlayer insulation film SIL may be formed using other methods.

Next, by applying a CMP (Chemical Mechanical Polishing) process to the second interlayer insulation film SIL, the second interlayer insulating film SIL is flattened (see FIG. 3). Then, a contact hole (not shown) is formed. Further, as required, by forming upper-layer wiring configuration (not shown), the main portion of the semiconductor device is completed.

In the semiconductor device SD described above, with respect to variations of the film thickness, in a plane of the semiconductor substrate SUB, of the wiring layer (mainly aluminum layer AF), a difference between the capacitance of the first capacitative element CEA and the capacitance of the second capacitative element CEB can be reduced. In this regard, an explanation thereof will be given in comparison with a semiconductor device according to a comparative example.

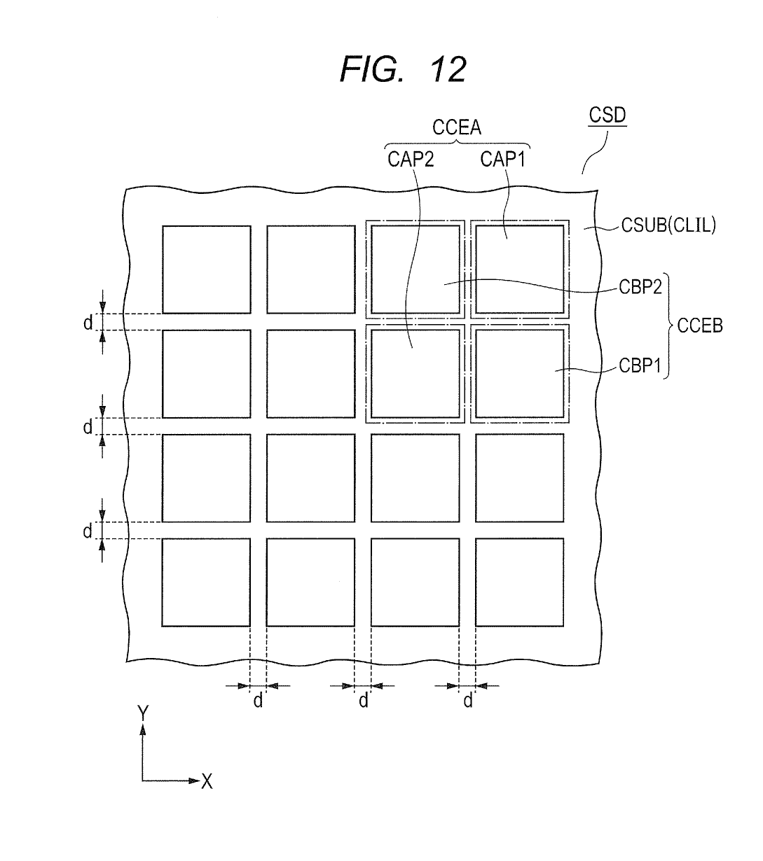

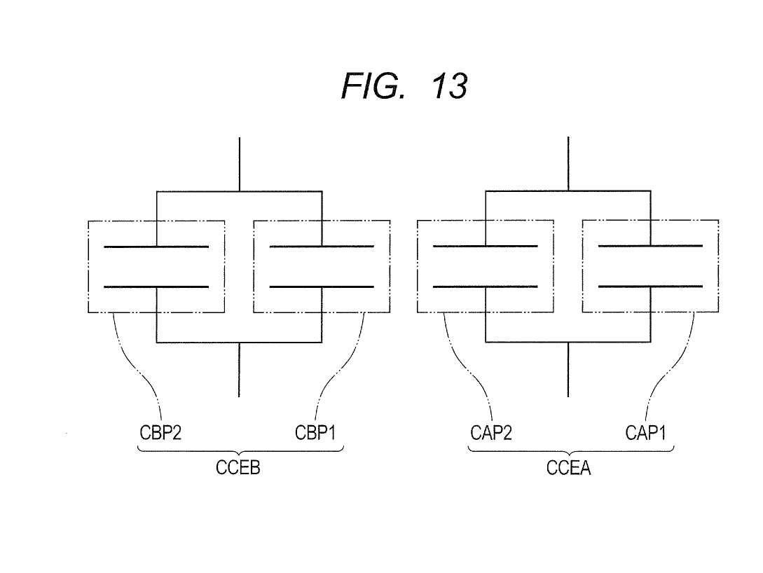

As shown in FIGS. 12 and 13, in the semiconductor device CSD according to the comparative example, the first capacitative element CCEA and the second capacitative element CCEB are formed as a pair of capacitative elements over a semiconductor substrate CSUB. The first capacitative element CCEA includes a first-capacitative element first part CAP1 and a first-capacitative element second part CAP2. The second capacitative element CCEB includes a second-capacitative element first part CBP1 and a second-capacitative element second part CBP2.

The first-capacitative element first part CAP1 and the first-capacitative element second part CAP2 intersect with the second-capacitative element first part CBP1 and the second-capacitative element second part CBP2, and are arranged in a direction of a diagonal line. As a result, in X-direction, the first-capacitative element first part CAP1 and the second-capacitative element second part CBP2 are arranged alternately, and the first-capacitative element second part CAP2 and the second-capacitative element first part CBP1 are arranged alternately. Moreover, in Y-direction, the first-capacitative element first part CAP1 and the second-capacitative element first part CBP1 are arranged alternately, and the first-capacitative element second part CAP2 and the second-capacitative element second part CBP2 are arranged alternately.

Next, more detailed explanation will be given to the configuration of the first capacitative element CAP and the second capacitative element CAB. As to the capacitative elements, in terms of degree of freedom of dielectric strength, development of the capacitative elements with use of wirings from the parallel flat-type capacitative elements has been in progress. That is, from the capacitative element having the configuration in which a dielectric is sandwiched by wirings vertically, the development of the capacitative element having the configuration in which a dielectric is sandwiched by wirings sideways has been in progress. In this type of capacitative element, a capacitance thereof is proportional to the product (equivalent to a plate area of the capacitative element) of the length of a wiring and the thickness of a wiring (layer). Therefore, when the thickness of the wiring layer varies, the capacitance will vary.

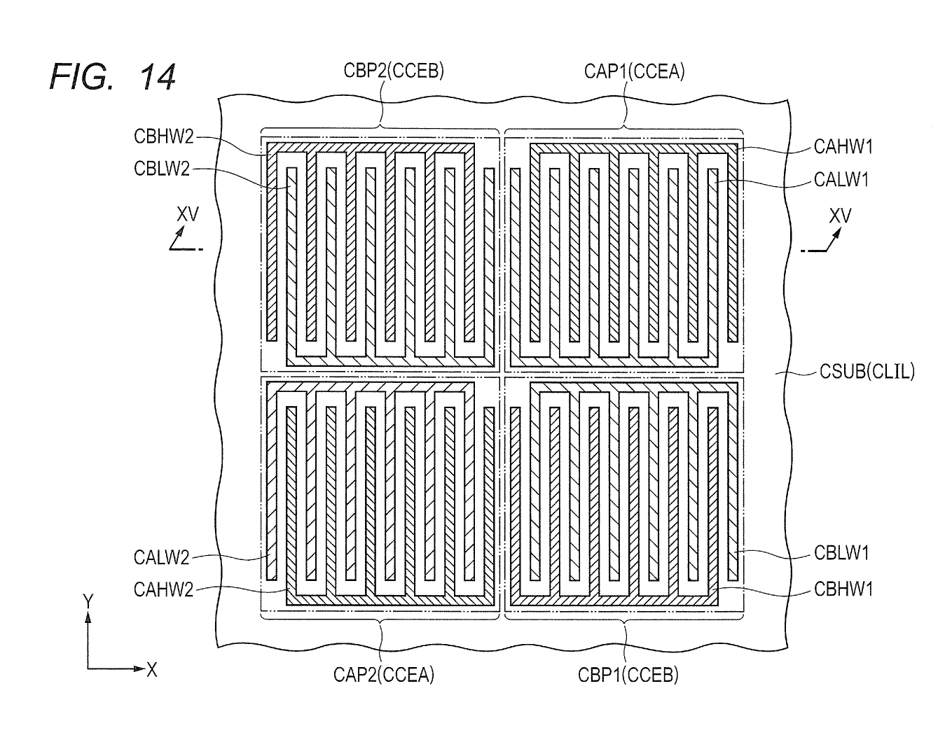

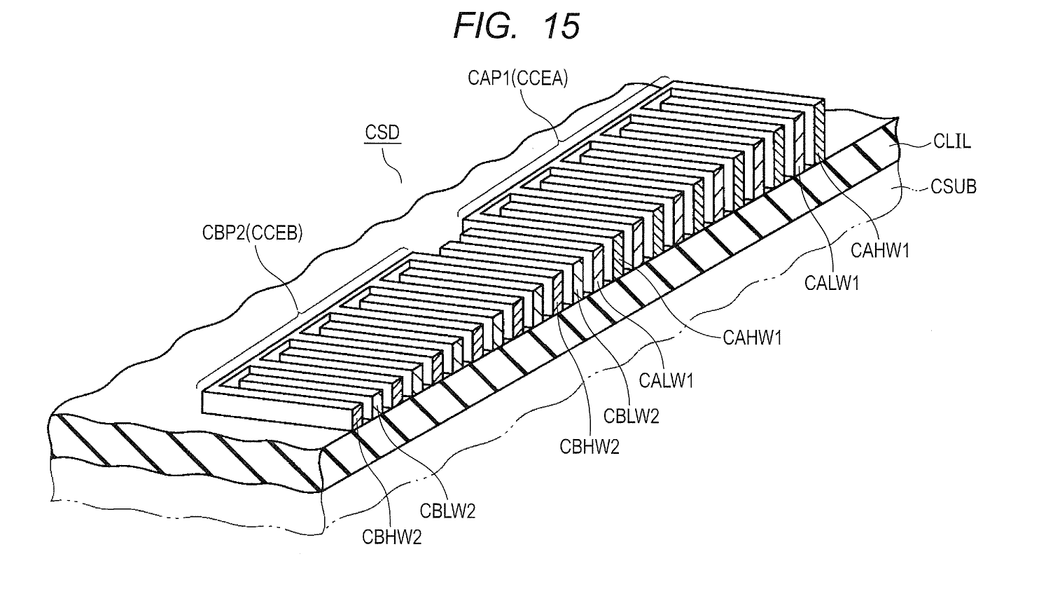

As shown in FIGS. 14 and 15, in the first-capacitative element first part CAP1 of the first capacitative element CCEA, a comb-like low-voltage side wiring CALW1 and a comb-like high-voltage side wiring CAHW1 are formed. The low-voltage side wiring CALW1 and the high-voltage side wiring CAHW1 are arranged such that their portions extending in X-direction engage with each other alternately. In the first-capacitative element second part CAP2, a comb-like low-voltage side wiring CALW2 and a comb-like high-voltage side wiring CAHW2 are formed. The low-voltage side wiring CALW2 and the high-voltage side wiring CAHW2 are arranged such that their portions extending in X-direction engage with each other alternately.

Next, in the second-capacitative element first part CBP1 of the second capacitative element CCEB, a comb-like low-voltage side wiring CBLW1 and a comb-like high-voltage side wiring CBHW1 are formed. The low-voltage side wiring CBLW1 and the high-voltage side wiring CBHW1 are arranged such that their portions extending in X-direction engage with each other alternately. In the second-capacitative element second part CBP2, a comb-like low-voltage side wiring CBLW2 and a comb-like high-voltage side wiring CBHW2 are formed. The low-voltage side wiring CBLW2 and the high-voltage side wiring CBHW2 are arranged such that their portions extending in X-direction engage with each other alternately.

In the semiconductor device according to the comparative example, when forming wiring layers such as an aluminum layer to be the low-voltage side wirings CALW1 to CB(L)HW2 and the high-voltage side wirings CAHW1 to CBHW2, the film thicknesses of the wiring layers may vary in the plane of the semiconductor substrate CSUB. FIG. 15 shows, in an exaggerated manner, one aspect of variations (unevenness) of the film thickness of the wiring layer in the plane of such a semiconductor substrate CSUB.

In order to reduce a difference between the capacitance of the first capacitative element CCEA and the capacitance of the second capacitative element CCEB caused by variations in film thickness of the wiring layer, the first-capacitative element first part CAP1 and the first-capacitative element second part CAP2 are arranged in the direction of a diagonal line. The second-capacitative element first part CBP1 and the second-capacitative element second part CBP2 are also arranged in the direction of a diagonal line.

However, the following has been confirmed by the present inventors. That is, with respect to a region whose film thickness of a wiring layer is relatively thin, depending on the arrangement of the first capacitative element CCEA and the second capacitative element CCEB, for example, the film thickness of the wiring layer of the first-capacitative element first part CAP1 only may be thinner than the film thickness of the wiring layer of each of the first-capacitative element second part CAP2, the second-capacitative element first part CBP1, and the second-capacitative element second part CBP2.

Further, it has been revealed that, as paired capacitative elements, there still arises a difference in capacitance between the first capacitative element CCEA and the second capacitative element CCEB and, for example, as the paired capacitative elements, in a comparator circuit where such a first capacitative element CCEA and a second capacitative element CCEB are used, comparison of a reference signal and an external signal cannot be performed correctly.

In contrast to the semiconductor device CSD of the comparative example, in the semiconductor device SD of the embodiment, as shown in FIG. 1 etc., the low-voltage side wiring LWA of the first capacitative element CEA and the low-voltage side wiring LWB of the second capacitative element CEB extend in X-direction, respectively, being spaced from each other in the main surface direction of the semiconductor substrate SUB while meandering along the main surface of the semiconductor substrate SUB.

To the meandering low-voltage side wiring LWA, the high-voltage side wiring HAW of the first capacitative element CEA is opposed, being spaced in the main surface direction of the semiconductor substrate SUB. Also, to the meandering low-voltage side wiring LWB, the high-voltage side wiring HWB of the second capacitative element CEB is opposed, being spaced in the main surface direction.

Therefore, in the plane of the semiconductor substrate SUB, even if there exist a region where the film thickness of the wiring layer is relatively thick and a region where the film thickness of the wiring layer is relatively thin, in the first capacitative element CEA and the second capacitative element CEB, the region whose wiring layer is thick and the region whose wiring layer is thin account for substantially the same percentage, allowing the film thicknesses of the wiring layers to be equalized. Consequently, as compared with the semiconductor device CSD of the comparative example where the region whose wiring layer is thick or thin exists, for example, only in the region of the one first-capacitative element first part CAP1, the difference between the capacitance of the first capacitative element CEA and the capacitance of the second capacitative element CEB can be reduced.

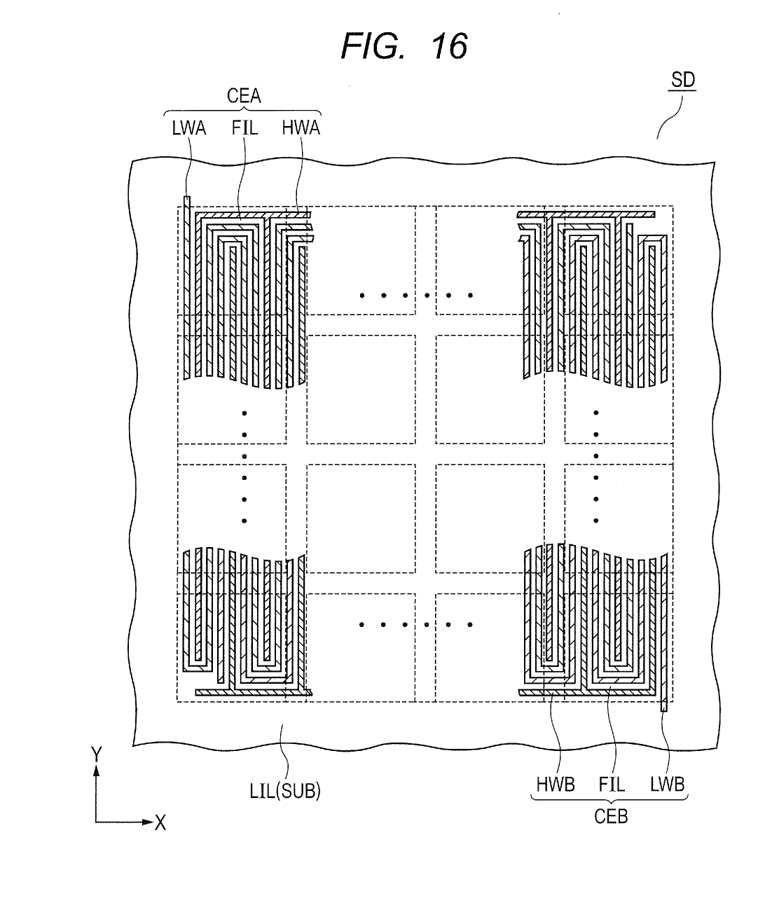

The first capacitative element CEA and the second capacitative element CEB which are shown in FIG. 1 etc. may be, for example, disposed in the region (region A) in which, for example, the first capacitative element CCEA of 4×4 and the second capacitative element CCEB shown in FIG. 12 (comparative example) are disposed. That is, as shown in FIG. 16, in Y-direction, the low-voltage side wiring LWA, the high-voltage side wiring HAW, the low-voltage side wiring LWB, and the high-voltage side wiring HWA (wiring layers) are extended, respectively. In X-direction, by increasing the number of meanderings, in each of the first capacitative element CEA and the second capacitative element CEA, the film thickness of the wiring layer becomes further equalized. As a result, the difference between the capacitance of the first capacitative element CEA and the capacitance of the second capacitative element CEB can be reduced reliably.

Moreover, when disposing the first capacitative element CEA and the second capacitative element CEB in the region A, there is not needed an isolation region (width d: see FIG. 12) for electrically isolating the first capacitative element CCEA and the second capacitative element CCEB, which can contribute to downsizing of the semiconductor device SD.

In the semiconductor device described above, for the interlayer insulating film, as an example, the case has been explained where the first interlayer insulating film FIL and the second interlayer insulating film SIL are formed. However, by omitting the first interlayer insulation film FIL and using an ordinary plasma CVD method, a single-layer interlayer insulation film corresponding to the second interlayer insulating film SIL may be formed. In this case, it is conceivable that each space between the wiring layers is not filled with the silicon nitride film sufficiently and a gap may be formed. However, so long as there is no problem in terms of the manufacturing process and performance of the semiconductor element, that gap may be allowable.

Moreover, by omitting the second interlayer insulation film SIL and using the high-density plasma CVD method, a single-layer interlayer insulating film corresponding to the first interlayer insulation film FIL may be formed. At this time, in a high-density plasma CVD apparatus, a film forming speed may be improved by changing the film forming conditions. In either case, so long as the interlayer insulation film serves to insulate sufficiently, the film forming method and the types of films etc. are not limitative.

Further, in the semiconductor device described above, as a wiring layer, the wiring layer mainly containing the aluminum layer has been shown as an example. However, a wiring layer containing a polysilicon layer may be used. In this case, for example, when forming a gate wiring using a polysilicon layer, the wiring layer can be formed at the same time.

### Second Embodiment

Now, a second example of the semiconductor device having a pair of MIM capacitative elements will be explained. In the first example, as a wiring layer, the wiring layer mainly containing aluminum has been described as an example (see FIG. 1). In the second example, a copper wiring will be described as a wiring layer.

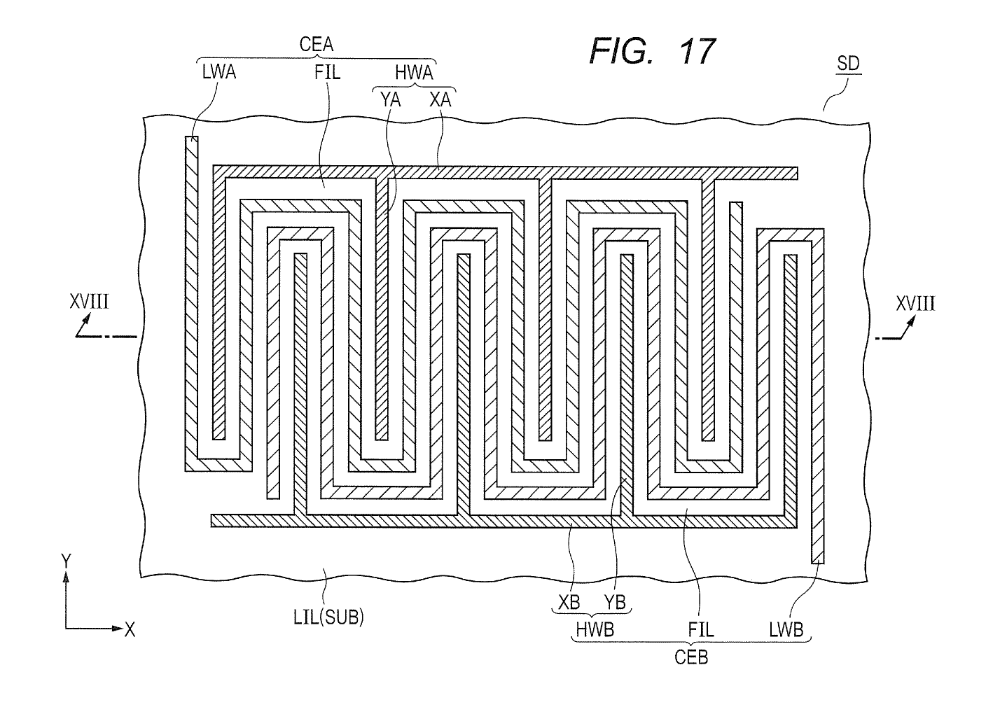

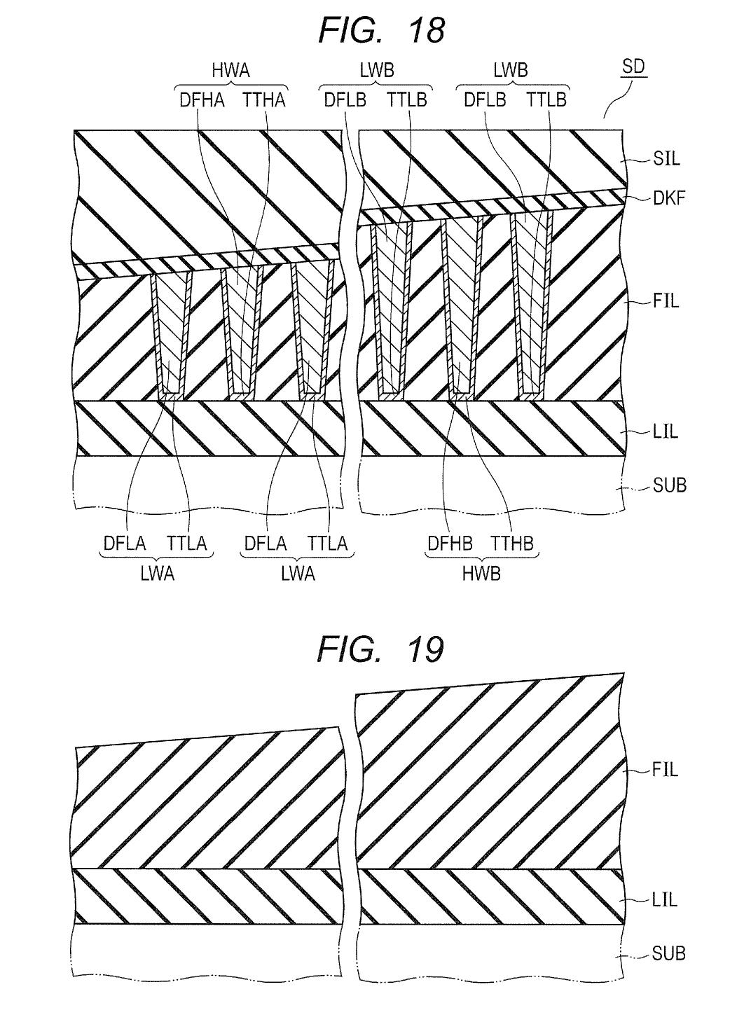

As shown in FIGS. 17 and 18, the low-voltage side wirings LWA, LWB and the high-voltage side wiring HWA,HWB are configured such that a copper film is laminated over a tantalum nitride layer as a barrier metal layer. The low-voltage side wiring LWA, the high-voltage side wiring HWA, the low-voltage side wiring LWB, and the high-voltage side wiring HWB are so formed as to pass through the first interlayer insulating film FIL. Also, FIG. 18 shows, in an exaggerated manner, the unevenness of the film thickness of the first interlayer insulating film FIL in the plane of the semiconductor substrate SUB.

In the low-voltage side wiring LWA, a copper film DFLA is formed over a tantalum nitride layer TTLA, and a copper film DFHA is formed over a tantalum nitride layer TTHA in the high-voltage side wiring HWA. In the low-voltage side wiring LWB, a copper film DFLB is formed over a tantalum nitride layer TTLB, and a copper film DFHB is formed over a tantalum nitride layer TTHB in the high-voltage side wiring HWB.

So as to cover the copper films DFLA, DFHA, DFLB, DFHB, etc., for example, a copper diffusion prevention film DKF containing a silicon nitride film is formed. Also, a second interlayer insulation film SIL is so formed as to cover the copper diffusion preventing film DKF. Since other configurations are similar to those of the semiconductor device SD shown in FIGS. 1 to 3, like reference characters are given to like members and the description thereof will not be repeated unless necessary.

Next, an explanation will be given to one example of the method of manufacturing the semiconductor device described above. After formation of a predetermined semiconductor element (not shown), such as a transistor, over the main surface of the semiconductor substrate, as shown in FIG. 19, for example, a lower interlayer insulation film LIL such as a silicon oxide film is so formed as to cover the main surface of the semiconductor substrate SUB. Next, a first interlayer insulation film FIL is so formed as to cover the lower interlayer insulation film LIL. In addition, FIG. 19 shows, in an exaggerated manner, the unevenness of the film thickness of the first interlayer insulation film FIL in the plane of the semiconductor substrate SUB. However, it is not intended to restrict the change in the film thickness of the first interlayer insulation film FIL.

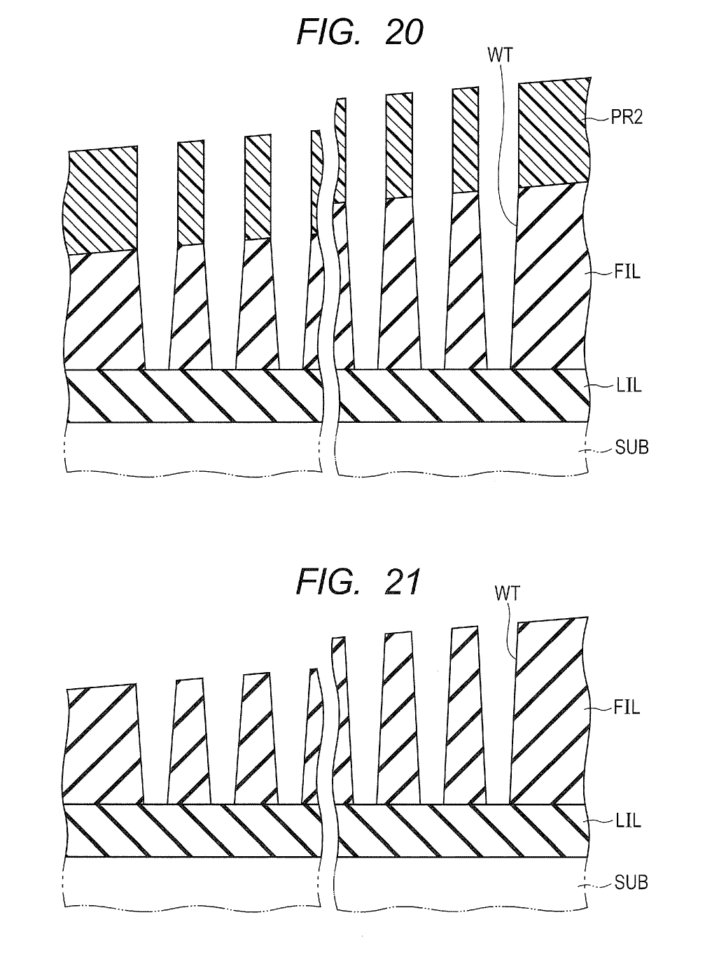

Next, the wiring is formed by a damascene method. As shown in FIG. 20, by applying a predetermined photomechanical process, a photo-resist pattern PR2 is formed. Next, using the photo-resist pattern PR2 as an etching mask, by applying plasma etching to the first interlayer insulating film FIL, a wiring trench WT reaching the lower interlayer insulation film LIL is formed.

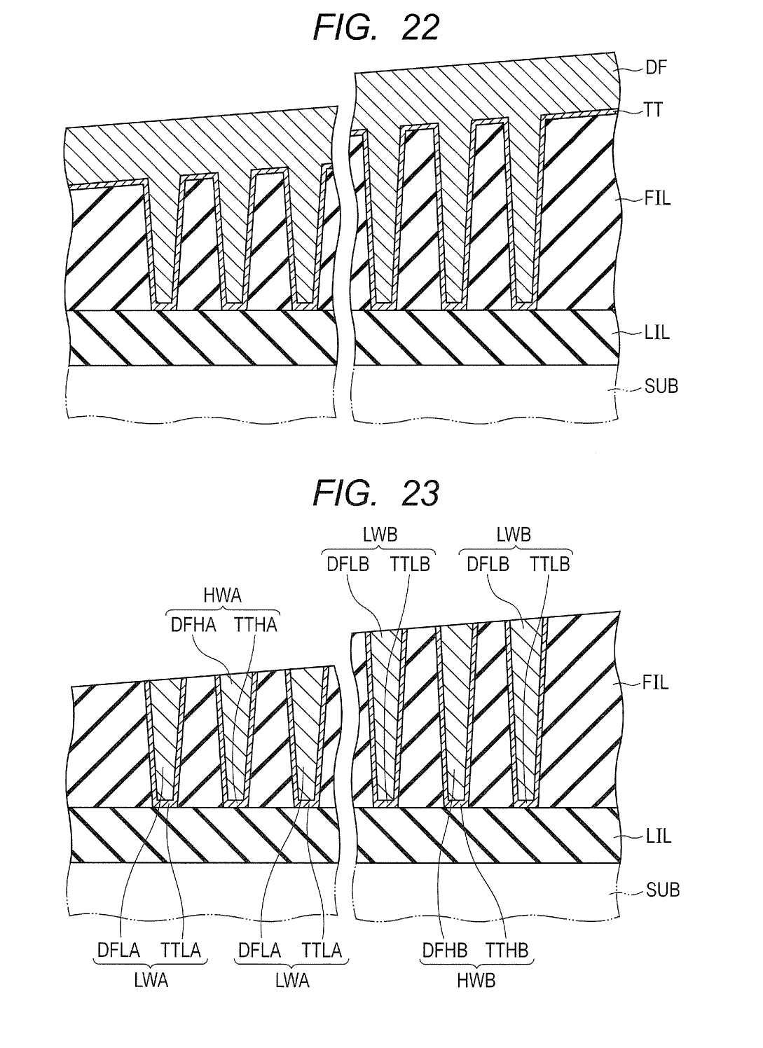

Next, as shown in FIG. 21, the photo-resist pattern PR2 is removed by performing oxygen asking. Next, as shown in FIG. 22, a tantalum nitride layer TT for preventing a copper diffusion is formed. Next, by a plating method, a copper film DF is formed over the surface of the tantalum nitride layer TT.

Next, as shown in FIG. 23, by performing chemical mechanical polishing, leaving a portion of the tantalum nitride layer TT and a portion of the copper film CF in the wiring trench WT, a portions of the copper film CF and a portion of the tantalum nitride layer TT located over an upper surface of the first interlayer insulation film FIL are removed. Thus, the low-voltage side wiring LWA, the high-voltage side wiring HWA, the low-voltage side wiring LWB, and the high-voltage side wiring HWB are so formed as to pass through the first interlayer insulation film FIL.

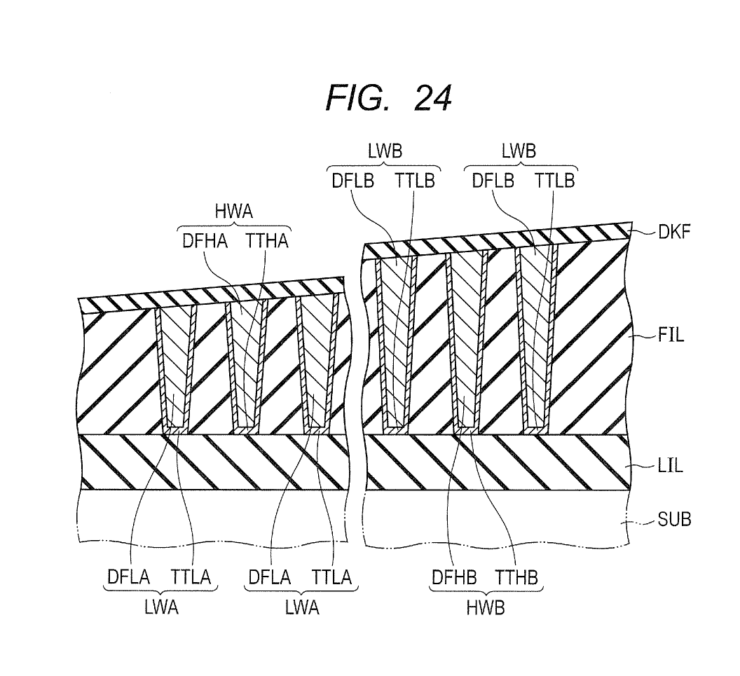

Next, as shown in FIG. 24, the copper diffusion preventing film DKF containing a silicon nitride film is so formed as to cover the exposed low-voltage side wiring LWA, the high-voltage side wiring HWA, the low-voltage side wiring LWB, and the high-voltage side wiring HWB, etc. for example, by the plasma CVD method. Next, in a process similar to the one shown in FIG. 10, a second interlayer insulation film SIL (not shown) is formed.

Next, by applying chemical mechanical polishing to the second interlayer insulation film, the second interlayer insulating film SIL is flattened (see FIG. 18). Then, a contact hole (not shown) is formed. Further, as required, by forming upper-layer wiring configuration (not shown), the main portion of the semiconductor device is completed.

In the semiconductor device SD described above, as in the semiconductor device shown in FIG. 1 etc., the low-voltage side wiring LWA of the first capacitative element CEA and the low-voltage side wiring LWB of the second capacitative element CEB extend in X-direction, respectively, being spaced from each other in the main surface direction of the semiconductor substrate SUB while meandering along the main surface of the semiconductor substrate SUB.

To the meandering low-voltage side wiring LWA, the high-voltage side wiring HAW of the first capacitative element CEA is opposed, being spaced from the low-voltage side wiring LWA in the main surface direction of the semiconductor substrate SUB. Also, to the meandering low-voltage side wiring LWB, the high-voltage side wiring HWB of the second capacitative element CEB is opposed, being spaced from the low-voltage side wiring LWB in the main surface direction.

As a result, in the plane of the semiconductor substrate SUB, even if there exist a region where the film thickness of the first interlayer insulating film FIL corresponding to the thickness of the wiring layer is relatively thick and a region where the film thickness is relatively thin, in the first capacitative element CEA and the second capacitative element CEB, the region whose wiring layer is thick and the region whose wiring layer is thin account for substantially the same percentage, allowing the film thicknesses of the wiring layers to be equalized. Consequently, being similar to the case described in First Embodiment, as compared with the semiconductor device CSD of the comparative example, it becomes possible to reduce the difference between the capacitance of the first capacitative element CEA and the capacitance of the second capacitative element CEB.

Further, in the semiconductor device SD described above, the low-voltage side wiring LWA and the high-voltage side wiring HWA of the first capacitative element CEA, and the low-voltage side wiring LWB and the high-voltage side wiring HWB of the second capacitative element CEB are formed by the damascene method as copper wirings in the first interlayer insulation film FIL. An opening corresponding to a wiring trench is formed in a photo resist in the photo-resist pattern PR2 at the time of forming the copper wirings by the damascene method (see FIG. 20).

Consequently, the pattern PR2 of the photo-resist is configured so as not to fall easily, allowing the copper wiring to be formed accurately. In particular, the damascene method is more advantageous as the width of the copper wiring and the spacing between the copper wirings become narrower. Moreover, as the spacing between the copper wirings gets narrower, it becomes possible to increase each electrostatic capacitance per unit area of the first capacitative element CEA and the second capacitative element CEB.

### Third Embodiment

Now, a third example of the semiconductor device having a pair of MIM capacitative elements will be explained. In the first example, the case where the low-voltage side wiring LWA of the first capacitative element CEA and the low-voltage side wiring LWB of the second capacitative element CEB are formed individually was explained (see FIG. 1).

In the third example, an explanation will be given to a case where the low-voltage side wiring LWA and the low-voltage side wiring LWB thereof are electrically short-circuited and used. As an aspect of electrically short-circuiting and using the low-voltage side wirings LWA and LWB, a shared low-voltage side wiring is used.

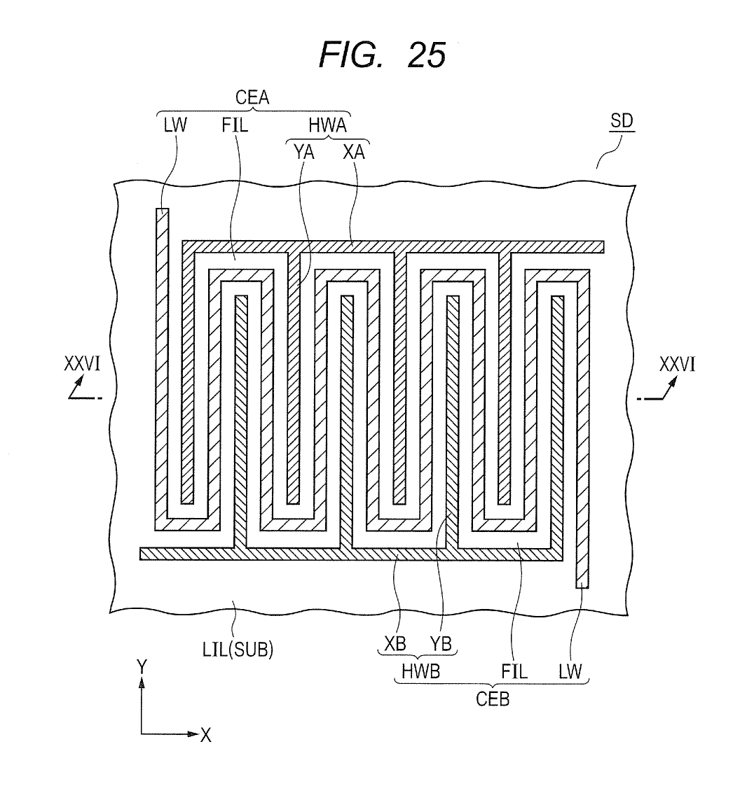

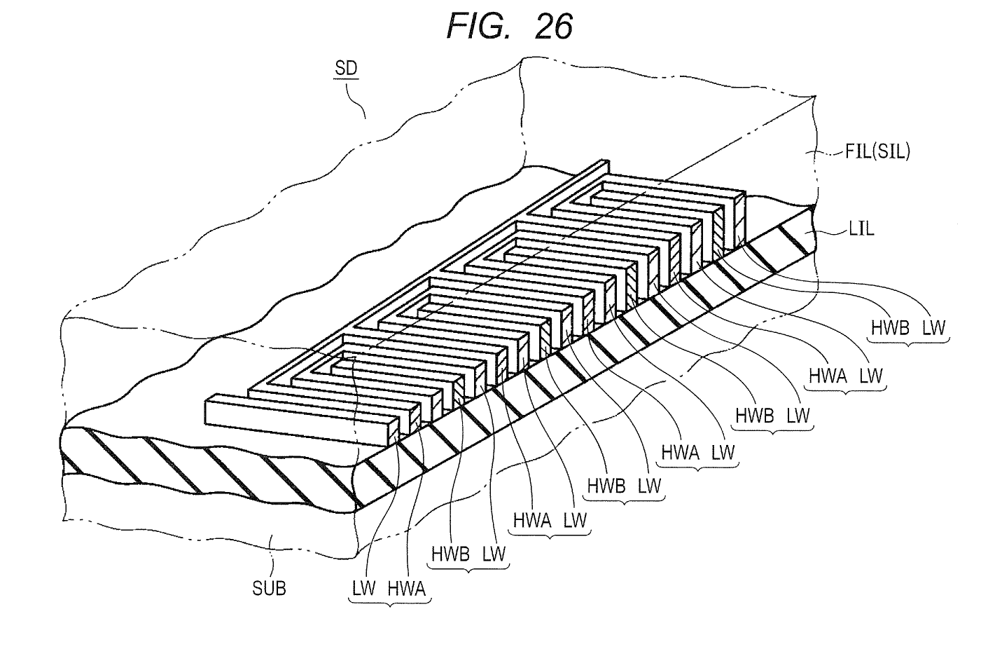

As shown in FIGS. 25 and 26, of the paired MIM capacitative elements, the first capacitative element CEA includes a shared low-voltage side wiring LW (first wiring), a high-voltage side wiring HAW (second wiring), and a part (dielectric) of the first interlayer insulation film FIL. Of the paired MIM capacitative elements, the second capacitative element CEB includes the shared low-voltage side wiring LW (first wiring), a high-voltage side wiring HWA (fourth wiring), and a part (dielectric) of the first interlayer insulation film FIL.

The shared low-voltage side wiring LW extends in X-direction while meandering along the main surface of the semiconductor substrate SUB. The high-voltage side wiring HAW is opposed to the low-voltage side wiring LW, being spaced from the low-voltage side wiring LW in the main surface direction. On the side opposite to where the high-voltage side wiring HWA is located with respect to the low-voltage side wiring LW, the high-voltage side wiring HWB is opposed to the low-voltage side wiring LW, being spaced from the low-voltage side wiring LW in the main surface direction.

As shown in FIG. 26, in one cross-section along X-direction, a first-capacitative element CEA wiring group including the high-voltage side wiring HWA and the low-voltage side wiring LW and a second-capacitative element CEB wiring group including the high-voltage side wiring HWB and the low-voltage side wiring LW are positioned alternately along X-direction.

Being similar to the case of the first example, the low-voltage side wiring LW, the high-voltage side wiring HWA, and the high-voltage side wiring HWB are of the three-layer configuration where an aluminum layer is laid between the two titanium nitride layers. Also, FIG. 26 shows, in an exaggerated manner, the unevenness (variations) of the thicknesses of the low-voltage side wiring LW, the high-voltage side wiring HWA, and the high-voltage side wiring HWB in the plane of the semiconductor substrate SUB. Since other configurations are similar to those of the semiconductor device SD shown in FIGS. 1 to 3, like reference characters are given to like members and the description thereof will not be repeated unless necessary.

Except that the low-voltage side wiring is the shared low-voltage side wiring LW, the semiconductor device described above can be manufactured by substantially the same manufacturing method as in the first example.

First, after the formation of the lower interlayer insulation film which covers the main surface of the semiconductor substrate, a first titanium nitride layer, an aluminum layer, and a second titanium nitride layer (neither is shown) are formed. Next, a photo-resist pattern (not shown) for patterning the shared low-voltage side wiring LW etc. is formed. Subsequently, using the photo-resist pattern as an etching mask, by performing plasma etching, the low-voltage side wiring LW, the high-voltage side wiring HAW, and the high-voltage side wiring HWA are formed (see FIG. 26).

Subsequently, a first interlayer insulation film FIL is so formed as to cover the low-voltage side wiring LW, the high-voltage side wiring HAW, and the high-voltage side wiring HWA. The main portion of the semiconductor device is completed (see FIG. 26) when a second interlayer insulation film SIF etc. are further so formed as to cover the first interlayer insulation film FIL (see FIG. 26).

In semiconductor device SD described above, the low-voltage side wiring LW shared by the first capacitative element CEA and the second capacitative element CEB extends in X-direction while meandering along the main surface of the semiconductor substrate SUB. To the meandering low-voltage side wiring LW, the high-voltage side wiring HAW of the first capacitative element CEA is opposed, being spaced from the low-voltage side wiring LW in the main surface direction of the semiconductor substrate SUB. Also, the high-voltage side wiring HWB of the second capacitative element CEB is opposed to the meandering low-voltage side wiring LW, being spaced from the low-voltage side wiring LW in the main surface direction.

Thus, as described in First Embodiment, in the plane of the semiconductor substrate SUB, even if there exist a region where the film thickness of the aluminum layer corresponding to the thickness of the wiring layer is relatively thin and a region where the film thickness is relatively thin, in the first capacitative element CEA and the second capacitative element CEB, the region whose wiring layer is thick and the region whose wiring layer is thin account for substantially the same percentage, allowing the film thicknesses of the wiring layers to be uniform. Consequently, as compared with the semiconductor device CSD (see FIG. 13 etc.) of the comparative example, a difference between the capacitance of the first capacitative element CEA and the capacitance of the second capacitative element CEB can be reduced.

Furthermore, in the semiconductor device SD described above, the low-voltage side wiring of the first capacitative element CEA and the low-voltage side wiring of the second capacitative element CEB serve as the shared low-voltage side wiring LW. Thus, as compared with the case where the two low-voltage side wirings are formed, the electrostatic capacitance per unit area as the MIM capacitance of the pair can be increased.

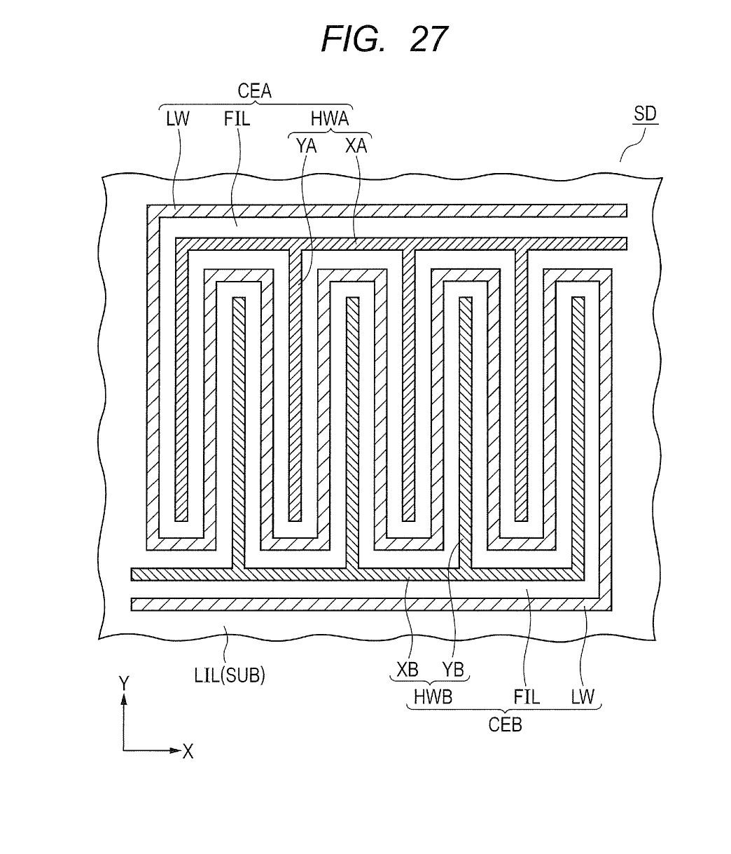

Also, in order to further secure an electrostatic capacitance, as shown in FIG. 27, the configuration may be such that one end of the low-voltage side wiring LW is extended in X-direction (positive) along the high-voltage side wiring HWA and the other end of the low-voltage side wiring LW is extended in X-direction (negative) along the high-voltage side wiring HWB.

In the semiconductor device SD described above, as the low-voltage side wiring LW, the high-voltage side wiring HWA, and the high-voltage side wiring HWB, a wiring layer mainly containing copper wiring may be employed.

### Fourth Embodiment

Now, a fourth example of the semiconductor device having a pair of MIM capacitative elements will be explained. In the first to third examples, as a wiring layer, the single-layer wiring layer was described as an example. In the fourth example, a two-layer wiring layer will be described as an example.

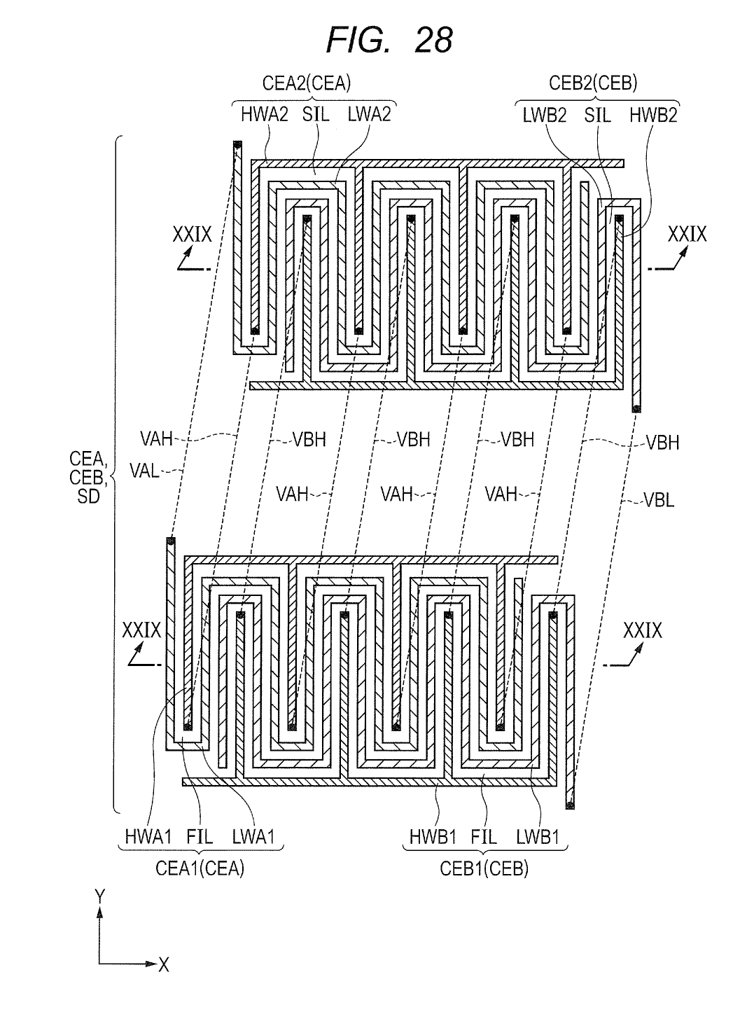

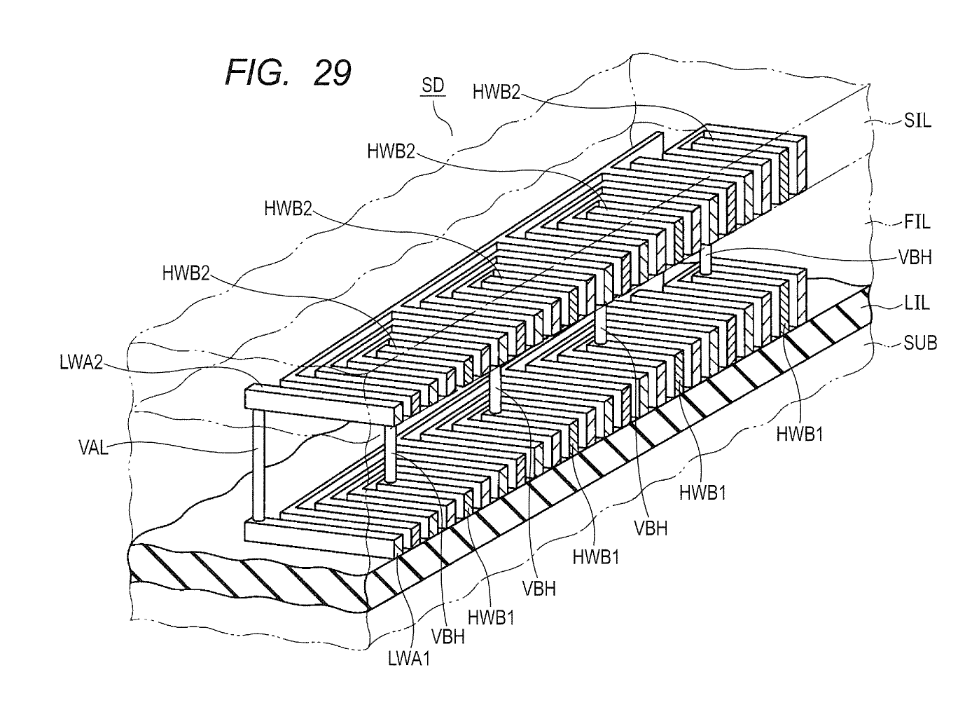

As shown in FIGS. 28 and 29, the first capacitative element CEA and the second capacitative element CEB include a first wiring layer and a second wiring layer. A first-capacitative element first part CEA1 of the first capacitative element CEA and a second-capacitative element first part CEB1 of the second capacitative element CEB are further formed of the first wiring layer. A first-capacitative element second part CEA2 of the first capacitative element CEA and a second-capacitative element second part CEB2 of the second capacitative element CEB are formed of the second wiring layer.

The first-capacitative element first part CEA1 includes a low-voltage side wiring LWA1, a high-voltage side wiring HWA1, and a first interlayer insulating film FIL. The first-capacitative element second part CEA2 includes a low-voltage side wiring LWA2, a high-voltage side wiring HWA2, and a second interlayer insulating film SIL. The low-voltage side wiring LWA1 and the low-voltage side wiring LWA2 are electrically coupled through a via hole VAL. The high-voltage side wiring HWA1 and the high-voltage side wiring HWA2 are electrically coupled through a via hole VAH.

The second-capacitative element first part CEB1 includes a low-voltage side wiring LWB1, a high-voltage side wiring HWB1, and the first interlayer insulating film FIL. The second-capacitative element second part CEB2 includes a low-voltage side wiring LWB2, a high-voltage side wiring HWB2, and the second interlayer insulating film SIL. The low-voltage side wiring LWB1 and the low-voltage side wiring LWB2 are electrically coupled through a via hole VBL. The high-voltage side wiring HWB1 and the high-voltage side wiring HWB2 are electrically coupled through a via hole VBH.

For the sake of simplicity, FIG. 28 shows that the first wiring layer is displaced from the second wiring layer and the predetermined wirings are electrically coupled with each other through the via holes VAL, VAH, VBL, and VHB. In the actual semiconductor device, however, the first wiring layer and the second wiring layer are so arranged as to overlap as seen in a plan view. In this regard, “as seen in a plan view” implies a two-dimensional pattern. In other word, it means a pattern as seen in a direction substantially perpendicular to the main surface of the semiconductor substrate SUB. In the semiconductor device SD, a potential of the first wiring layer and a potential of the second layer overlapped as seen in a plan view are set to the same value.

FIG. 29 shows, in an exaggerated manner, the unevenness (variations) in the thicknesses, in the plane of the semiconductor substrate SUB, of the low-voltage side wirings LWA1, LWB1 and the high-voltage side wirings HWA1, HWB1 in the first layer, respectively. Similarly, FIG. 29 shows, in an exaggerated manner, the unevenness (variations) of the thicknesses, in the plane of the semiconductor substrate SUB, of the low-voltage side wirings LWA2, LWB2 and the high-voltage side wirings HWA2, HWB2 in the second layer, respectively.

As in the case of the first example, the low-voltage side wirings LWA1, LWB1 and the high-voltage side wirings HWA1, HWB1 in the first layer are of the three-layer configuration in which an aluminum layer is laid between two titanium nitride layers. Moreover, the low-voltage side wirings LWA2, LWB2 and the high-voltage side wirings HWA2, HWB2 in the second layer are also of the three-layer configuration in which an aluminum layer is laid between two titanium nitride layers. In addition, since other configurations are similar to those of the semiconductor device SD shown in FIGS. 1 to 3, like reference characters are given to like members and the description thereof will not be repeated unless necessary.

The semiconductor device SD described above has two wiring layers and can be manufactured by repeating substantially the same manufacturing method as in the first example.

First, a lower interlayer insulation film which covers the main surface of the semiconductor substrate is formed. Then, a first titanium nitride layer, an aluminum layer, and a second titanium nitride layer (neither is shown) are formed. Next, a photo-resist pattern (not shown) for patterning the first wiring layer is formed. Then, using the photo-resist pattern as an etching mask, by performing the plasma etching, the low-voltage side wiring LWA1, LWB1 and the high-voltage side wirings HWA1, HWB1 are formed (see FIG. 29).

Next, a first interlayer insulation film FIL is formed so as to cover the low-voltage side wirings LWA1, LWB1 and the high-voltage side wirings HWA1, and HWB1. Next, through the first interlayer insulating film FIL, via holes VAH, VAL, and VBH are so formed as to be electrically coupled to the low-voltage side wirings LWA1, LWB1 and the high-voltage side wirings HWA1, HWB1, respectively.

Next, a first titanium nitride layer, an aluminum layer, and a second titanium nitride layer (neither is shown) are formed. Then, a photo-resist pattern (not shown) for patterning the second-layer wiring layer is formed. Subsequently, using the photo-resist pattern as an etching mask, by performing plasma etching, the low-voltage side wirings LWA2, LWB2 and the high-voltage side wirings HWA2, HWB2 are formed (see FIG. 29).

The low-voltage side wiring LWA2 comes to be electrically coupled with the low-voltage side wiring LWA1 through the via hole VAL, and the low-voltage side wiring LWB2 comes to be electrically coupled with the low-voltage side wiring LWB1 through the via hole VBL. The high-voltage side wiring HWA2 comes to be electrically coupled with the high-voltage side wiring HWA1 through the via hole VAH. Further, the high-voltage side wiring HWB2 comes to be electrically coupled with the high-voltage side wiring HWB1 through the via hole VBH.

Subsequently, when the second insulating film SIF etc. are so formed as to cover the low-voltage side wirings LWA2, LWB2 and the high-voltage side wirings HWA2, HWB2, the main portion of the semiconductor device is completed (see FIG. 29).

In the semiconductor device SD described above, first, the low-voltage side wiring LWA1 of the first-capacitative element first part CEA1 and the low-voltage side wiring LWB1 of the second-capacitative element second part CEB1 extend in X-direction, respectively, being spaced from each other in the main surface direction of the semiconductor substrate SUB while meandering along the main surface of the semiconductor substrate SUB.

To the meandering low-voltage side wiring LWA1, the high-voltage side wiring HAW1 of the first-capacitative element first part CEA1 is opposed, being spaced from the low-voltage side wiring LWA1 in the main surface direction of the semiconductor substrate SUB. Also, to the meandering low-voltage side wiring LWB1, the high-voltage side wiring HWB1 of the second-capacitative element first part CEB1 is opposed, being spaced from the low-voltage side wiring LWB1 in the main surface direction.

Moreover, the low-voltage side wiring LWA2 of the first-capacitative element second part CEA2 and the low-voltage side wiring LWB2 of the second-capacitative element second part CEB2 extend in X-direction, respectively, being spaced from each other in the main surface direction of the semiconductor substrate SUB while meandering along the main surface of the semiconductor substrate SUB.

To the meandering low-voltage side wiring LWA2, the high-voltage side wiring HAW2 of the first-capacitative element second part CEA2 is opposed, being spaced from the low-voltage side wiring LWA2 in the main surface direction of the semiconductor substrate SUB. Further, to the meandering low-voltage side wiring LWB2, the high-voltage side wiring HWB2 of the second-capacitative element second part CEB2 is opposed, being spaced from the low-voltage side wiring LWB2 in the main surface direction.

Consequently, as explained in First Embodiment, in the first capacitative element CEA and the second capacitative element CEB, the film thickness of the first-layer wiring layer and the film thickness of the second-layer wiring layer are equalized, respectively. As a result, a difference between the capacitance of the first-capacitative element first part CEA1 and the capacitance of the second-capacitative element first part CEB1 can be reduced. Also, a difference between the capacitance of the first capacitative element second part CEA2 and the capacitance of the second-capacitative element second part CEB2 can be reduced.

Thus, it becomes possible to reduce the difference between the capacitance of the first capacitative element CEA in which the first-capacitative element first part CEA1 and the first capacitative element second part CEA2 are coupled in parallel and the capacitance of the second capacitative element CEB in which the second-capacitative element first part CEB1 and the second-capacitative element second part CEB2 are coupled in parallel.

Further, in the semiconductor device SD described above, the first-capacitative element first part CEA1 and the second-capacitative element first part CEB1 are formed of the first wiring layer. Also, the first-capacitative element second part CEA2 and the second-capacitative element second part CEB2 are formed of the second wiring layer. The first capacitative element CEA and the second capacitative element CEB are of the laminated configuration. Accordingly, the electrostatic capacitance per unit area can be increased.

In the first capacitative element CEA, the first-capacitative element first part CEA1 and the first-capacitative element second part CEA2 are electrically coupled through via holes VAL and VAH. Further, in the second capacitative element CEB, the second-capacitative element first part CEB1 and the second-capacitative element second part CEB2 are electrically coupled through via holes VBL and the VBH. The number of via holes VAL, VAH, VBL, and VBH is not limitative. By forming many via holes VAL, VAH, VBL, and VBH, electrostatic capacitance between every two via holes can be increased and, as a result, the electrostatic capacitance per unit area can be increased.

Further, it is desirable for the via holes to have symmetrical properties. Moreover, instead of via holes being formed, the first-capacitative element first part and the second-capacitative element first part may serve as one capacitative element and first-capacitative element second part and the second-capacitative element second part may serve as another capacitative element. Also, capacitative elements may be laminated so as to reduce the area per unit capacitance. Furthermore, in the semiconductor device SD described above, the wiring layer mainly containing aluminum has been shown as an example. However, as in Second Embodiment, a copper wiring may be employed.

### Fifth Embodiment

Now, a fifth example of the semiconductor device having a pair of MIM capacitative elements will be explained. In the fourth example, the case has been described as an example where the potential of the first-layer wiring layer and the potential of the second-layer wiring layer overlapping in a plan view are the same. In the fifth example, a case will be described where the potential of the first-layer wiring layer and the potential of the second-layer wiring layer overlapping in a plan view are different.

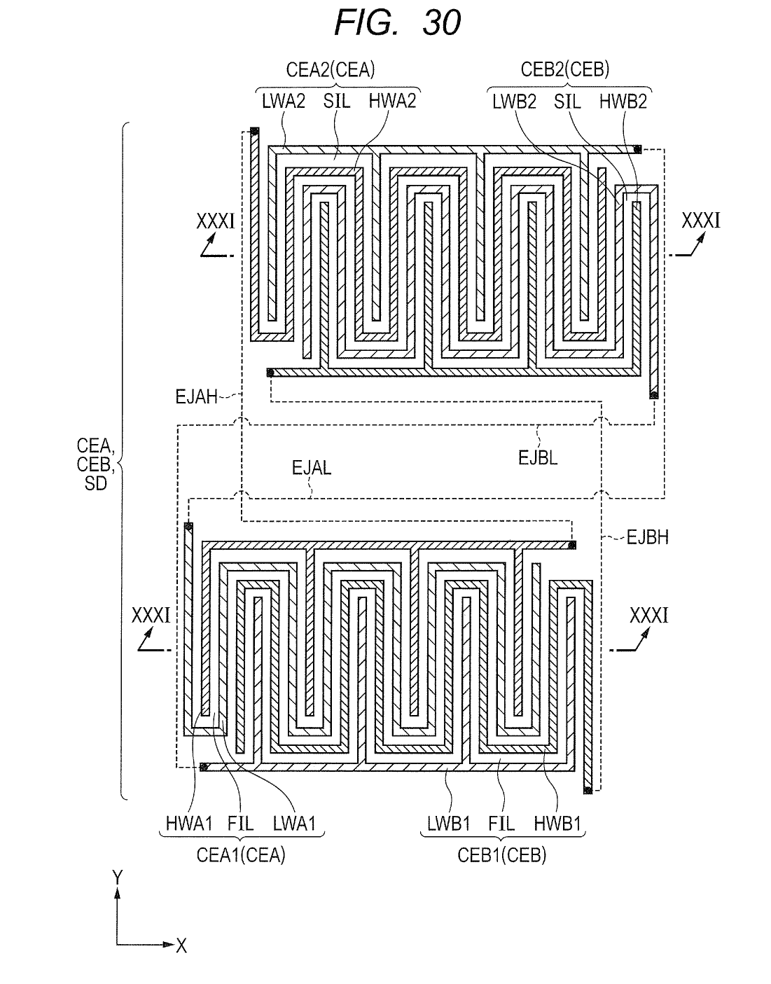

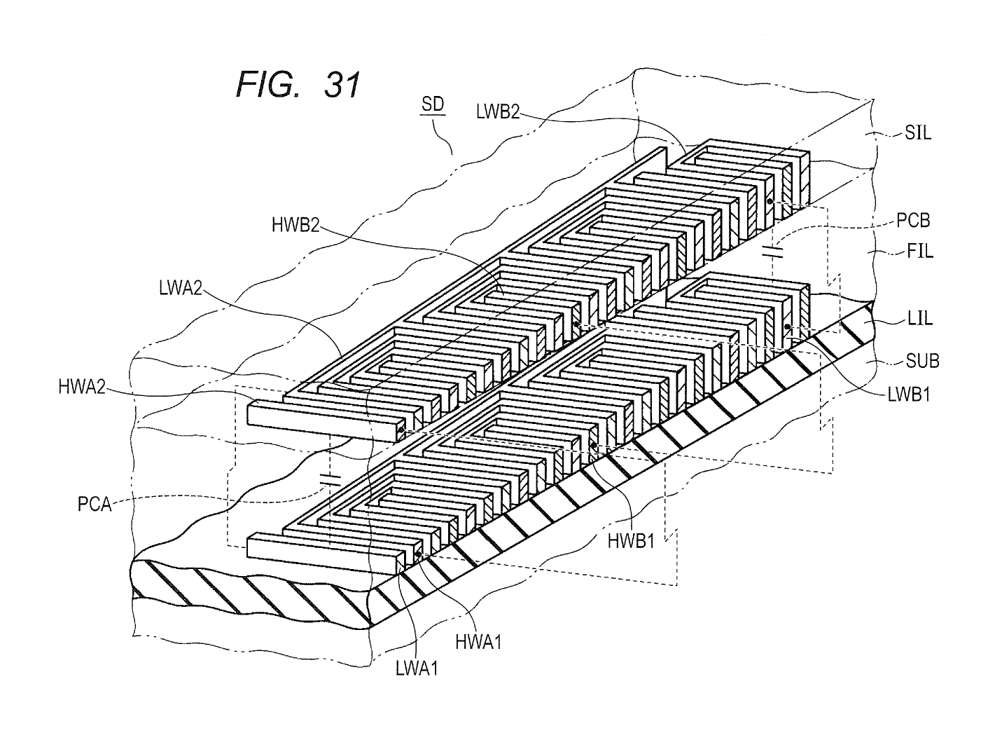

As shown in FIGS. 30 and 31, a first-capacitative element first part CEA1 of the first capacitative element CEA and a second-capacitative element first part CEB1 of the second capacitative element CEB are formed of the first-layer wiring layer. Also, a first-capacitative element second part CEA2 of the first capacitative element CEA and a second-capacitative element second part CEB2 of the second capacitative element CEB are formed of the second-layer wiring layer.

The first-capacitative element first part CEA1 includes a low-voltage side wiring LWA1, a high-voltage side wiring HWA1, and the first interlayer insulating film FIL. The first-capacitative element second part CEA2 includes a low-voltage side wiring LWA2, a high-voltage side wiring HWA2, and the second interlayer insulating film SIL. The low-voltage side wiring LWA1 and the low-voltage side wiring LWA2 are electrically coupled through a wiring EJAL. The high-voltage side wiring HWA1 and the high-voltage side wiring HWA2 are electrically coupled through a wiring EJAH.

The second-capacitative element first part CEB1 includes a low-voltage side wiring LWB1, a high-voltage side wiring HWB1, and the first interlayer insulating film FIL. The second-capacitative element second part CEB2 includes a low-voltage side wiring LWB2, a high-voltage side wiring HWB2, and the second interlayer insulating film SIL. The low-voltage side wiring LWB1 and the low-voltage side wiring LWB2 are electrically coupled through the wiring EJBL. The high-voltage side wiring HWB1 and the high-voltage side wiring HWB2 are electrically coupled through the wiring EJBH. In addition, the wirings EJAH, EJAL, EJBH and EJBL are arranged in a region outside the region where the first capacitative element CEA and the second capacitative element CEB are formed.

In FIG. 30, for the sake of simplicity, the first wiring layer is displaced from the second wiring layer and a drawing is shown in which predetermined wiring layers are electrically coupled through the wirings EJAH, EJAL, EJBH and EJBL, respectively. In the actual semiconductor device, however, the first wiring layer and the second wiring layer are overlapped in a plan view. Moreover, in the semiconductor device SD, a potential of the first wiring layer and a potential of the second wiring layer overlapped in a plan view are set to be different.

FIG. 31 shows, in an exaggerated manner, the unevenness (variations) of the thicknesses of the first-layer low-voltage side wirings LWA1, LWB1 and the high-voltage side wirings HWA1, HWB1 in the plane of the semiconductor substrate SUB. Similarly, FIG. 31 also shows, in an exaggerated manner, the unevenness (variations) of the thicknesses of the second-layer low-voltage side wirings LWA2, LWB2 and the high-voltage side wirings HWA2, HWB2 in the plane of the semiconductor substrate SUB.

As in the first example, the low-voltage side wirings LWA1, LWB1 and the high-voltage side wirings HWA1, HWB1 in the first layer are of the three-layer configuration in which an aluminum layer is laid between two titanium nitride layers. Further, the low-voltage side wirings LWA2, LWB2 and the high-voltage side wirings HWA2, HWB2 in the second layer are also of the three-layer configuration in which an aluminum layer is laid between two titanium nitride layers. Since other configurations are similar to those of the semiconductor device SD shown in FIGS. 1 to 3, like reference characters are given to like members and the description thereof will not be repeated unless necessary.

The semiconductor device SD described above has two wiring layers, and can be manufactured by repeating substantially the same manufacturing process as in the first example.

First, a lower interlayer insulating film covering the main surface of the semiconductor substrate is formed. Then, a first titanium nitride layer, an aluminum layer, and a second titanium nitride layer (neither is shown) are formed. Next, a photo-resist pattern (not shown) for patterning the first wiring layer is formed. Further, using the photo-resist pattern as an etching mask, by performing plasma etching, the low-voltage side wirings LWA1, LWB1 and the high-voltage side wiring HWA1, HWB1 are formed (see FIG. 31).

Next, the first interlayer insulating film FIL is so formed as to cover the low-voltage side wirings LWA1, LWB1 and the high-voltage side wirings HWA1, HWB1. Then, the first titanium nitride layer, the aluminum layer, and the second titanium nitride layer (neither is shown) are formed. Further, a photo-resist pattern (not shown) for patterning the second-layer wiring layer is formed. Next, using the photo-resist pattern as an etching mask, by performing plasma etching, the low-voltage side wirings LWA2, LWB2 and the high-voltage side wirings HWA2, HWB2 are formed (see FIG. 31).

Next, the second interlayer insulation film SIF etc. are so formed as to cover the low-voltage side wirings LWA2, LWB2 and the high-voltage side wirings HWA2, HWB2. Moreover, in a suitable process of a series of processes, the first capacitative element CEA and the second capacitative element CEB are formed, and in a predetermined region outside the region, wirings EJAH, EJAL, EJBH and EJBL (see FIG. 30) are formed. Thus, the main portion of the semiconductor device is completed (see FIG. 31).

In the semiconductor device SD described above, first, the low-voltage side wiring LWA1 of the first-capacitative element first part CEA1 and the high-voltage side wiring HWB1 of the second-capacitative element first part CEB1 extend in X-direction, respectively, being spaced from each other in the main surface direction of the semiconductor substrate SUB while meandering along the main surface of the semiconductor substrate SUB.

To the meandering low-voltage side wiring LWA1, the high-voltage side wiring HAW1 of the first-capacitative element first part CEA1 is opposed, being spaced from the low-voltage side wiring LWA1 in the surface direction of the semiconductor substrate SUB. Also, to the meandering high-voltage side wiring HWB1, the low-voltage side wiring LWB1 of the second-capacitative element first part CEB1 is opposed, being spaced from the high-voltage side wiring HWB1 in the main surface direction.

Moreover, the high-voltage side wiring HWA2 of the first-capacitative element second part CEA2 and the low-voltage side wiring LWB2 of the second capacitative element second part CEB2 extend in X-direction, respectively, being spaced from each other in the main surface direction of the semiconductor substrate SUB while meandering along the main surface of the semiconductor substrate SUB.

To the meandering high-voltage side wiring HWA2, the low-voltage side wiring LAW2 of the first-capacitative element second part CEA2 is opposed, being spaced from the high-voltage side wiring HWA2 in the main surface direction of the semiconductor substrate SUB. Also, to the meandering low-voltage side wiring LWB2, the high-voltage side wiring HWB2 of the second-capacitative element second part CEB2 is opposed from the low-voltage side wiring LWB2 in the main surface direction.

Consequently, as explained in First Embodiment, in the first capacitative element CEA and the second capacitative element CEB, the film thickness of the first-layer wiring layer and the film thickness of the second-layer wiring layer are equalized, respectively. As a result, a difference between the capacitance of the first-capacitative element first part CEA1 and the capacitance of the second-capacitative element first part CEB1 can be reduced. Also, a difference between the capacitance of the first-capacitative element second part CEA2 and the capacitance of the second-capacitative element second part CEB2 can be reduced.

In this way, there can be reduced the difference between the capacitance of the first capacitative element CEA in which the first-capacitative element first part CEA1 and the first capacitative element second part CEA2 are coupled in parallel and the capacitance of the second capacitative element CEB in which the second-capacitative element first part CEB1 and the second-capacitative element second part cEB2 are coupled in parallel.

In the semiconductor device SD described above, the first-capacitative element first part CEA1 and the second-capacitative element first part CEB1 are formed of the first wiring layer, and the first-capacitative element second part CEA2 and the second-capacitative element second part CEB2 are formed of the second wiring layer. The first capacitative element CEA and the second capacitative element CEB are of the laminated configuration.

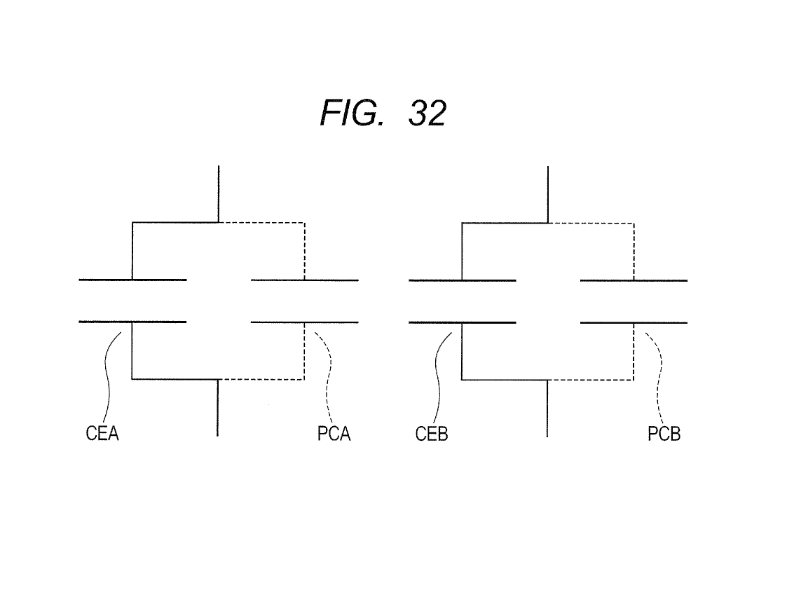

Furthermore, in the semiconductor device SD, the potential of the first-layer wiring layer and the potential of the second-layer wiring layer, overlapping in a plan view, are different. Consequently, as shown in FIGS. 31 and 32, a parasitic capacitance PCA between the first-layer wiring layer and the second-layer wiring layer is further added to the capacitance of the first capacitative element CEA. Moreover, a parasitic capacitance PCB between the first-layer wiring layer and the second-layer wiring layer is further added to the capacitance of the second capacitative element CEB. As a result, the electrostatic capacity per unit area can be increased further.

In the semiconductor device SD described above, as the wiring for the first and second capacitative elements CEA and CEB, the wiring mainly containing aluminum has been shown as an example. However, as in the case of Second Embodiment, a copper wiring may be employed.

### Sixth Embodiment

Now, a sixth example of the semiconductor device having a pair of MIM capacitative elements will be explained.

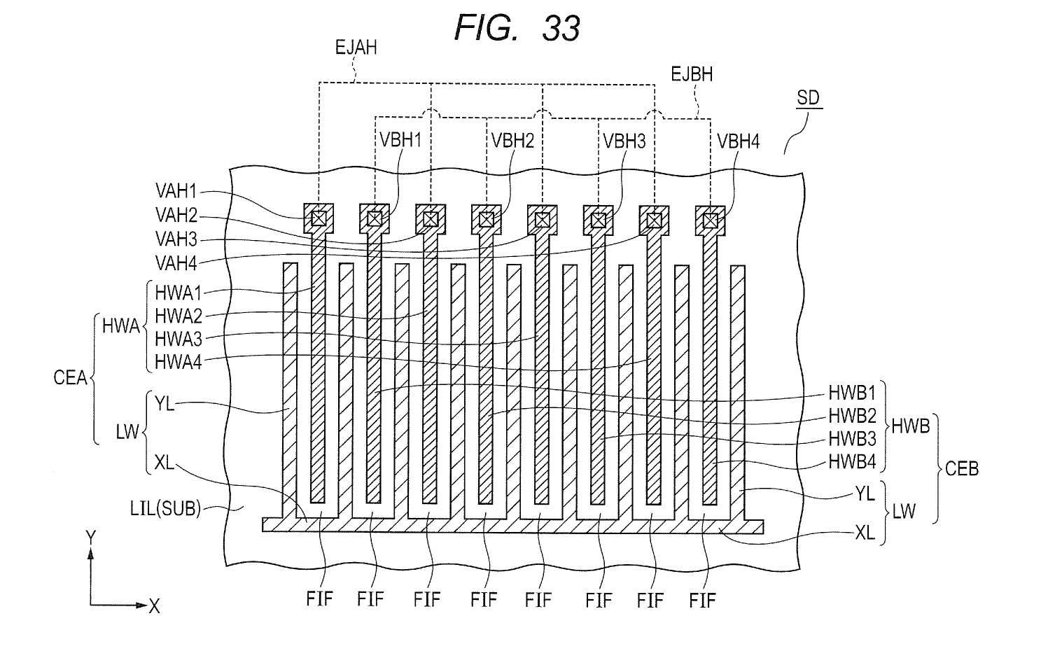

As shown in FIG. 33, of the paired MIM capacitative elements, the first capacitative element CEA includes a shared low-voltage side wiring LW, a high-voltage side wiring HWA, and a part of the first interlayer insulation film FIL. Of the paired MIM capacitative elements, the second capacity CEB includes the shared low-voltage side wiring LW, a high-voltage side wiring HWB, and a part of the first interlayer insulation film FIL.

The low-voltage side wiring LW includes: an X-direction extending part XL extending in X-direction; and a plurality of Y-direction extending parts YL extending, respectively, from the X-direction extending part XL in Y-direction being substantially perpendicular to X-direction. The high-voltage side wiring HWA includes a plurality of high-voltage side wirings HWA1, HWA2, HWA3, and HWA4 extending in Y-direction, respectively. Further, the high-voltage side wiring HWB includes a plurality of high-voltage side wirings HWB1, HWB2, HWB3, and HWB4 extending, respectively, in Y-direction.

With respect to the high-voltage side wirings HWA1, HWA2, HWA3, HWA4, and the high-voltage side wirings HWB1, HWB2, HWB3 and HWB4, the high-voltage side wiring HWA1 is arranged in the region located between one Y-direction extending part YL and the adjacent other Y-direction extending part YL, and the high-voltage side wiring HWB1 is arranged in a region between the other Y-direction extending part YL and the adjacent still other Y-direction extending part YL. The high-voltage side wirings HWA1, HWA2, HWA3, HWA4 and the high-voltage side wirings H_WB1, HWB2, HWB3, and HWB4 arranged alternately along X-direction are opposed to the low-voltage wide wiring LW.

The high-voltage side wirings HWA1, HWA2, HWA3, and HWA4 are electrically coupled to one another by the wiring EJAH through via holes VAH1, VAH2, VAH3, and VAH4, respectively. The high-voltage side wirings HWB1, HWB2, HWB3, and HWB4 are electrically coupled to one another by the wiring EJBH through via holes VBH1, VBH2, VBH3, and VBH4. The wiring EJAH and the wiring EJBH are formed, respectively, in layers different from the ones in which the high-voltage side wirings HWA and HWB are disposed.

The semiconductor device SD described above can be manufactured by substantially the same manufacturing method as in the third example.

First, a lower interlayer insulation film which covers the main surface of the semiconductor substrate is formed. Then, a first titanium nitride layer, an aluminum layer, and a second titanium nitride layer (neither is shown) are formed. Then, a photo-resist pattern (not shown) for patterning the shared low-voltage side wiring LW etc. is formed. Next, using the photo-resist pattern as an etching mask, by performing plasma etching, the low-voltage side wiring LW, the high-voltage side wiring HAW, and the high-voltage side wiring HWA are formed (see FIG. 33).

Next, the first interlayer insulation film FIL is so formed as to cover the low-voltage side wiring LW, the high-voltage side wiring HAW, and the high-voltage side wiring HWA. Further, a second interlayer insulation film (not shown) etc. are so formed as to cover the first interlayer insulation film FIL.

Subsequently, via holes VAH1, VAH2, VAH3, VAH4 and the wiring EJAH for electrically coupling the high-voltage side wirings HWA1, HWA2, HWA3, and HWA4 to one another are formed. Also, via holes VBH1, VBH2, VBH4 and the wiring EJBH for electrically coupling the high-voltage side wirings HWB1, HWB2, HWB3, and HWB$ to one another are formed. Thus, the main portion of the semiconductor device is completed (see FIG. 33).

In the semiconductor device SD described above, the shared low-voltage side wiring LW shared by the first capacitative element CEA and the second capacitative element CEB includes; an X-direction extending part XL extending in X-direction; and a plurality of Y-direction extending parts YL each extending from the X-direction extending part XL in Y-direction being substantially perpendicular to X-direction.

With respect to the Y-direction extending parts YL, a high-voltage side wiring HWA1 is disposed in a region between one of the Y-direction extending parts YL and the other adjacent Y-direction extending parts YL. Also, a high-voltage side wiring HWB1 is disposed in a region between the other Y-direction extending part and still other adjacent Y-direction extending part YL. The high-voltage side wiring HWA and the high-voltage side wiring HWB are disposed alternately along the X-direction.

Thus, as described in First Embodiment, each of the first capacitative element CEA and the second capacitative element CEB, the film thickness of the wiring layer is equalized. As a result, a difference between the capacitance of the first capacitative element CEA and the capacitance of the second capacitative element CEB can be reduced.

In the semiconductor device SD described above, each of the X-direction extending part XL and the Y-direction extending part YL included in the low-voltage side wiring LW side wiring LW extends linearly. Moreover, the high-voltage side wirings HWA and HWB extend linearly in Y-direction, respectively. As a result, when patterning the low-voltage side wiring LW and the high-voltage side wirings HWA, HWB, portions where the photo resist tends to get rounded and the photo-resist pattern becomes curved are reduced and unfavorable effects due to the photo-resist getting rounded can be suppressed.

In the semiconductor device SD described above, as the wiring layer for the first capacitative element CEA and the second capacitative element CEB, the wiring layer mainly containing aluminum has been shown as an example. However, as in Second Embodiment, a copper wiring may be employed. Further, with regard to the semiconductor device SD described in the above embodiment, various combinations as required are possible.

While the invention achieved by the present inventors has been specifically described above based on the embodiments thereof, the present invention is not limited thereto. It will be appreciated that various changes and modifications can be made in the invention within the scope not departing from the gist thereof.

What is claimed is:

1. A semiconductor device, comprising:
a semiconductor substrate having a main surface; and
a first capacitative element and a second capacitative element formed over the main surface, respectively,
wherein the first capacitative element includes:
a first wiring extending in a first direction while meandering along the main surface;
a second wiring opposed to the first wiring, and being spaced from the first wiring in the main surface direction; and
a first dielectric interposed between the first wiring and the second wiring, and
wherein the second capacitative element includes:
a third wiring, on the side opposite to where the second wiring is located with respect to the first wiring, extending in the first direction, and being spaced from the first wiring in the main surface direction, while meandering along the first wiring;
a fourth wiring opposed to the third wiring, and being spaced from the third wiring in the main surface direction; and
a second dielectric interposed between the third wiring and the fourth wiring.

2. The semiconductor device according to claim 1,
wherein the second wiring includes:
a first extending part extending in the first direction; and
a plurality of second extending parts extending linearly from the first extending part, respectively, in a second direction intersecting the first direction, and spaced from each other in the first direction,
wherein each of the second extending parts is so arranged as to enter toward a section of the meandering first wiring being away from the first extending part,
wherein the fourth wiring includes:
a third extending part extending in the first direction; and
a plurality of fourth extending parts extending linearly from the third extending part, respectively, in the second direction, being spaced from each other in the first direction, and
wherein each of the fourth extending parts is so arranged as to enter toward a section of the meandering third wiring being away from the third extending part.

3. The semiconductor device according to claim 2, wherein, in one cross-section along the first direction, a first-capacitative element wiring group including the first wiring, the second wiring, and the first wiring and a second-capacitative element wiring group including the third wiring, the fourth wiring, and the third wiring are positioned alternately along the first direction.

4. The semiconductor device according to claim 1,
wherein the first wiring includes:
a first-wiring first part; and
a first-wiring second part formed in a layer different from the one in which the first-wiring first part is formed,
wherein the second wiring includes:
a second-wiring first part formed of the same layer as the first-wiring first part; and
a second-wiring second part formed of the same layer as the first-wiring second part,
wherein the first dielectric includes:
a first-dielectric first part interposed between the first-wiring first part and the second-wiring first part; and
a first-dielectric second part interposed between the first-wiring second part and the second-wiring second part,
wherein the third wiring includes:
a third-wiring first part; and
a third-wiring second part formed in a layer different from the one in which the third-wiring first part is formed,
wherein the fourth wiring includes:
a fourth-wiring first part formed of the same layer as the third-wiring first part; and
a fourth-wiring second part formed of the same layer as the third-wiring second part,
wherein the second dielectric includes:
a second-dielectric first part interposed between the third-wiring first part and the fourth-siring first part; and
a second-wiring second part interposed between the third-wiring second part and the fourth-wiring second part,
wherein the first capacitative element includes:
a first-capacitative element first part containing the first-wiring first part, the second-wiring first part, and the first-dielectric first part; and
a first-capacitative element second part containing the first-wiring second part, the second-wiring second part, and the first-dielectric second part, and
wherein the second capacitative element includes:
a second-capacitative element first part containing the third-wiring first part, the fourth-wiring first part, and the second-dielectric first part; and
a second-capacitative element second part containing the third-wiring second part, the fourth-wiring second part, and the second-dielectric second part.

5. The semiconductor device according to claim 4,
wherein each of the first-wiring first part, the second-wiring first part, the third-wiring first part, and the fourth-wiring first part is so arranged as to overlap, in a plan view, with each of the first-wiring second part, the second-wiring second part, the third-wiring second part, and the fourth-wiring second part, and
wherein the wirings overlapping with each other in a plan view is electrically coupled so that their potentials may be the same.

6. The semiconductor device according to claim 4,
wherein each of the first-wiring first part, the second-wiring first part, the third-wiring first part, and the fourth-wiring first part are so arranged as to overlap, in a plan view, with each of the first-wiring second part, the second-wiring second part, the third-wiring second part, and the fourth-wiring second part, and
wherein the wirings overlapping with each other in a plan view is electrically coupled so that their potentials may be different.

7. The semiconductor device according to claim 1, wherein the first wiring, the second wiring, the third wiring, and the fourth wiring are formed according to a minimum line width and a minimum pitch of the design rule.

8. A semiconductor device, comprising:
a semiconductor substrate having a main surface; and
a first capacitative element and a second capacitative element formed over the main surface, respectively,
wherein the first capacitative element includes:
a first wiring extending in a first direction while meandering along the main surface;
a second wiring opposed to the first wiring, and being spaced from the first wiring in the main surface direction; and
a first dielectric interposed between the first wiring and the second wiring, and
wherein the second capacitative element includes:
the first wiring;
a third wiring, on the side opposite to where the second wiring is located with respect to the first wiring, opposed to the first wiring, and being spaced from the first wiring in the main surface direction; and
a second dielectric interposed between the first wiring and the third wiring.

9. The semiconductor device according to claim 8,
wherein the second wiring includes:
a first extending part extending in the first direction; and
a plurality of second extending parts extending linearly from the first extending part, respectively, in a second direction intersecting the first direction, and spaced from each other in the first direction,
wherein each of the second extending parts is so arranged as to enter toward a section of the meandering first wiring being away from the first extending part,
wherein the third wiring includes:
a third extending part extending in the first direction; and
a plurality of fourth extending parts extending linearly from the third extending part, respectively, in the second direction and spaced from each other in the first direction, and
wherein each of the fourth extending parts is so arranged as to enter toward the section of the meandering first wiring being away from the third extending part.

10. The semiconductor device according to claim 9, wherein, in one cross-section along the first direction, a first-capacitative element wiring group including the first wiring and the second wiring and a second-capacitative element wiring group including the first wiring and the third wiring are arranged alternately along the first direction.

11. The semiconductor device according to claim 8, wherein the first wiring, the second wiring, and the third wiring are formed according to a minimum line width and a minimum pitch of the design rule.

12. A semiconductor device, comprising:
a semiconductor substrate having a main surface; and
a first capacitative element and a second capacitative element formed over the main surface, respectively,
wherein the first capacitative element includes:
a first wiring;
a second wiring opposed to the first wiring, and being spaced from the first wiring in the main surface direction; and
a first dielectric interposed between the first wiring and the second wiring,
wherein the second capacitative element includes:
the first wiring;
a third wiring, on the side opposite to the second wiring with respect to the first wiring, opposed to the first wiring being spaced from the first wiring in the main surface direction; and
a second dielectric interposed between the first wiring and the third wiring,
wherein the first wiring includes:
a first extending part extending in a first direction along the main surface;
a plurality of second extending parts extending from the first extending part, respectively, in a second direction intersecting with the first direction, and being arranged at intervals in the first direction,
wherein the second wiring and the third wiring extend in the second direction, respectively,
wherein, with respect to the second wirings and the third wirings being arranged alternately in the first direction, among the second extending parts, the second wiring is disposed in a region between one of the second extending parts and the other adjacent second extending part and, among the second extending parts, the third wiring is disposed in a region between the other second extending part and still the other adjacent second extending part, and
wherein the second wirings are electrically coupled with each other and the third wirings are electrically coupled with each other.

13. The semiconductor device according to claim 12, wherein, in one-cross section along the first direction, a first-capacitative element wiring group including the first wiring and the second wiring and a second-capacitative element wiring group including the first wiring and the third wiring are positioned alternately along the first direction.

14. The semiconductor device according to claim 12, wherein the first wiring, the second wiring, and the third wiring are formed according to a minimum line width and a minimum pitch of the design rule.
